(19) United States
(12) Patent Application Publication
(10) Pub. No.: US 2025/0324525 A1
(43) Pub. Date: Oct. 16, 2025

(54) ELECTRONIC DEVICE COMPRISING FRAME HAVING CLADDING PORTION AND METHOD OF MANUFACTURING THE SAME

(71) Applicant: SAMSUNG ELECTRONICS CO., LTD., Suwon-si (KR)

(72) Inventors: Changhyeok SHIN, Suwon-si (KR); Joungki PARK, Suwon-si (KR); Seungchang BAEK, Suwon-si (KR); Hyeongsam SON, Suwon-si (KR); Junghyun IM, Suwon-si (KR); Sungho CHO, Suwon-si (KR)

(73) Assignee: SAMSUNG ELECTRONICS CO., LTD., Suwon-si (KR)

(21) Appl. No.: 19/178,183

(22) Filed: Apr. 14, 2025

Related U.S. Application Data
(63) Continuation of application No. PCT/KR2025/003577, filed on Mar. 19, 2025.

(30) Foreign Application Priority Data
Apr. 16, 2024 (KR) 10-2024-0051034
May 17, 2024 (KR) 10-2024-0064700

(51) Int. Cl. H05K 5/02

(52) U.S. Cl. CPC H05K 5/0226

(57) ABSTRACT

An electronic device may include a frame defining at least a portion of a side surface of the electronic device, and a support portion on an inner side of the frame. The frame may include a corner portion defining a portion of the side surface and including a first metal, and a side portion defining another portion of the side surface and including a clad structure in which an outer portion including the first metal and an inner portion including a second metal are joined. The support portion may be connected to the corner portion and the side portion by welding.

### CROSS-REFERENCE TO RELATED APPLICATIONS

This application is a bypass continuation application of International Application No. PCT/KR2025/003577, filed on Mar. 19, 2025, which claims priority to Korean Application No. 10-2024-0051034, filed in the Korean Intellectual Property Office on Apr. 16, 2024, and Korean Application No. 10-2024-0064700, filed in the Korean Intellectual Property Office on May 17, 2024, the disclosures of which are herein incorporated by reference in their entireties.

### BACKGROUND

### 1. Field

Embodiments of the present disclosure relate to an electronic device including a frame having a cladding portion and a method of manufacturing the same.

### 2. Brief Description of Background Art

An electronic device may include a front portion on which a display is disposed, a rear portion on which a rear cover is disposed, and a side frame between the front portion and the rear portion. The side frame may be formed of, for example, a metal material having a certain level of durability and/or strength or higher. However, as interest in the aesthetics of the exterior of electronic devices increases, attempts are being made to form a material of at least a portion of the side frame using various alloys. The side frame may be physically and/or electrically connected to a support member in the electronic device. Various processes may be required to couple the side frame and the support members formed of metal.

The aforementioned information may be provided as related art to aid in understanding the present disclosure. No claim or determination is made as to whether any of the above matters constitutes prior art with respect to the present disclosure.

### SUMMARY

According to some example embodiments of the present disclosure, an electronic device may be provided and include: a frame; and a support portion on an inner side of the frame, wherein the frame includes: a corner portion defining a first portion of a side surface of the electronic device, the corner portion including a first metal; and a side portion defining a second portion of the side surface, the side portion including a clad structure including an outer portion and an inner portion that are joined together, wherein the outer portion includes the first metal, and the inner portion includes a second metal, different from the first metal, and wherein the support portion is connected to the corner portion and the side portion by welding.

According to some example embodiments of the present disclosure, an electronic device may be provided and include: a display; a rear cover; and a frame structure at least partially between the display and the rear cover, wherein the frame structure includes: a first side portion defining a first portion of a first side surface of the electronic device, the first side portion including a first clad structure including a first metal and a second metal, the first metal of the first clad structure being farther than the second metal of the first clad structure towards an outside of the electronic device; a second side portion defining a first portion of a second side surface of the electronic device, the second side portion including a second clad structure including the first metal and the second metal, the first metal of the second clad structure being farther than the second metal of the second clad structure towards the outside of the electronic device; a corner portion defining, between the first side portion and the second side portion, a second portion of the first side surface and a second portion of the second side surface, the corner portion including a first antenna feed including the first metal; and a support portion supporting the display, the support portion connected to the first side portion and the corner portion, and including the second metal.

According to some example embodiments of the present disclosure, a foldable electronic device may be provided and include: a hinge module; a first housing connected to the hinge module and configured to fold about the hinge module; a second housing connected to the hinge module and configured to fold about the hinge module; and a hinge cover connected to the hinge module, wherein at least a portion of the first housing, the second housing, and the hinge cover include a frame of the foldable electronic device, wherein the foldable electronic device further includes a support portion inside the frame, wherein the frame includes: a hinge side frame portion connected to the hinge cover and including at least a portion defining a first portion of a side surface of the foldable electronic device in a state in which the first housing and the second housing are folded; an edge frame portion opposite to the hinge side frame portion and defining a second portion of the side surface; and a corner frame portion on one side of the edge frame portion and defining a corner portion of the side surface, wherein the hinge side frame portion and the corner frame portion include a first metal, wherein the edge frame portion includes a clad structure including the first metal and a second metal, that is different from the first metal, and wherein the support portion is connected to the corner frame portion and the edge frame portion by welding.

### BRIEF DESCRIPTION OF DRAWINGS

FIG. 1A is a front perspective view of an electronic device according to an embodiment.

FIG. 1B is a rear perspective view of the electronic device according to an embodiment.

FIG. 1C is an exploded perspective view of the electronic device according to an embodiment.

FIG. 2A is a front perspective view of an electronic device according to an embodiment.

FIG. 2B is a plan view illustrating a rear surface of an electronic device according to an embodiment.

FIG. 2C is a partial exploded perspective view of an electronic device of FIGS. 2A and 2B including a hinge device according to an embodiment.

FIG. 3A is a front perspective view of an electronic device according to an embodiment.

FIG. 3B is a plan view illustrating a rear surface of an electronic device according to an embodiment.

FIG. 3C is a partial exploded perspective view of the electronic device of FIGS. 3A and 3B including a hinge device according to an embodiment.

FIG. 4 is view schematically illustrating a form of a frame of the electronic device according to an embodiment.

FIG. 5 is a view schematically illustrating a form of the frame of the electronic device according to an embodiment, excluding an injection-molded material.

FIG. 6 is a view for describing a manufacturing and coupling process for a frame of an electronic device according to an embodiment.

FIGS. 7A to 7J are views schematically illustrating the manufacturing and coupling process for a frame of an electronic device according to an embodiment.

FIG. 8 is a view illustrating a structure in which a side portion of a frame and a first support member and a second support member are coupled according to an embodiment.

FIG. 9 is a view illustrating a structure in which a corner portion of a frame and a first support member and a second support member are coupled according to an embodiment.

FIG. 10 is a view illustrating a form of a frame before a printed circuit board is mounted thereon according to an embodiment.

FIGS. 11A and 11B are views illustrating a contact portion of a frame according to an embodiment.

FIG. 12 is a view illustrating a form of a frame after a printed circuit board is mounted thereon according to an embodiment.

FIGS. 13A and 13B are views illustrating a form in which the frame and the printed circuit board are electrically connected according to an embodiment.

FIGS. 14A and 14B are views illustrating a form in which a frame of an electronic device according to an embodiment is formed using stainless steel.

FIG. 15 is a view schematically illustrating a portion of a frame of an electronic device according to an embodiment.

FIG. 16 is a view schematically illustrating a portion of a frame of an electronic device according to an embodiment.

### DETAILED DESCRIPTION

With respect to the description of the drawings, the same or similar reference signs may be used for the same or similar elements.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, various non-limiting example embodiments will be described with reference to the accompanying drawings. However, this is not intended to limit the present disclosure to the specific example embodiments. Various modifications, equivalents, and/or alternatives of the example embodiments of the present disclosure are included within the spirit and scope of the present disclosure.

Example embodiments of the disclosure relate to an electronic device including frame coupled by cladding and thermal bonding, and a method of manufacturing the same. According to an embodiment, a portion of the frame of the electronic device may include a clad metal, and the frame may be coupled to a frame inner support member through welding and insert injection molding. In this way, for example, the frame and the support member may be stably joined, and deformation or breakage of the frame may be prevented or reduced, thereby reducing or preventing problems that may occur regarding antenna performance. In addition, for example, a corner portion of the frame of the electronic device may be formed of a single metal, allowing the curvature formed by the corner portion to be variously implemented.

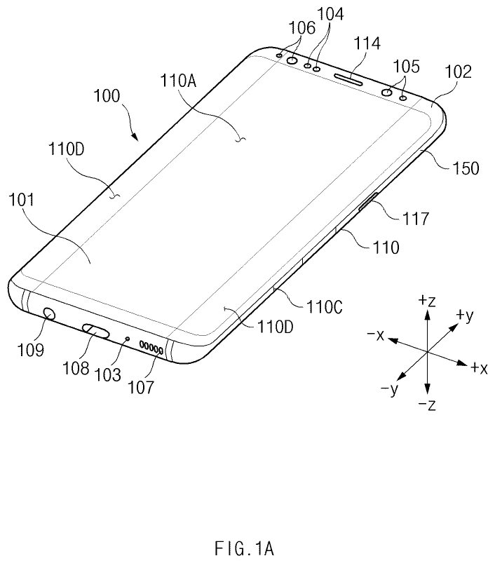

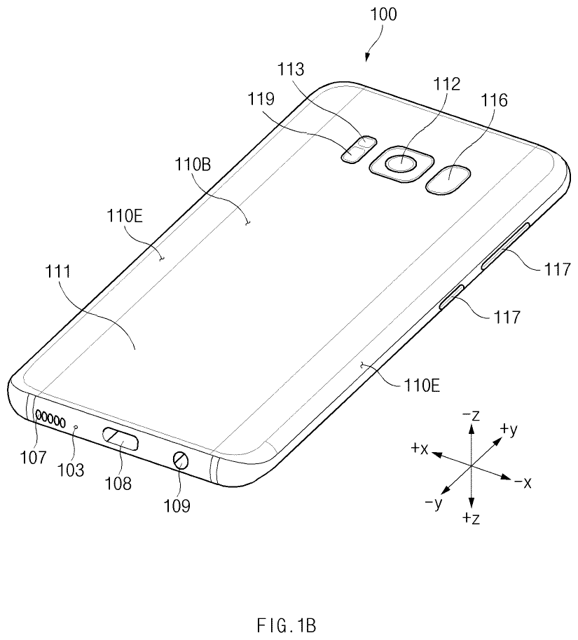

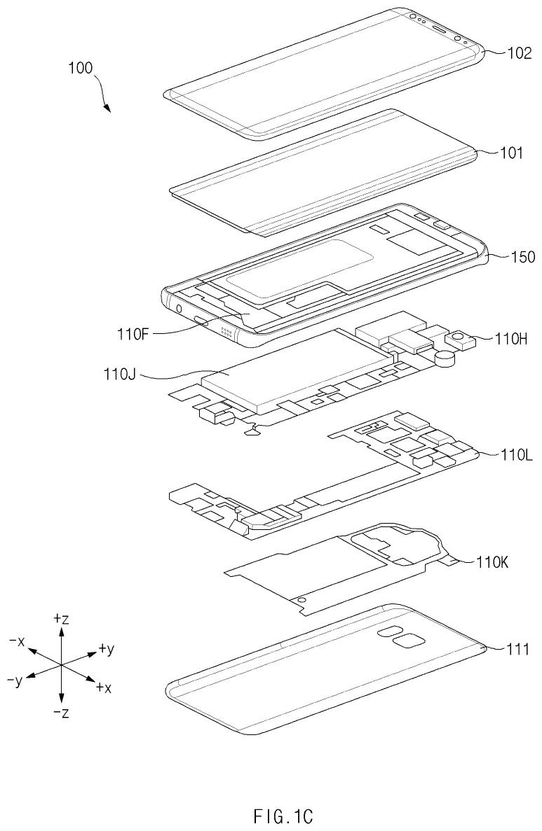

FIG. 1A is a front perspective view of an electronic device according to an embodiment.

FIG. 1B is a rear perspective view of the electronic device according to an embodiment.

FIG. 1C is an exploded perspective view of the electronic device according to an embodiment.

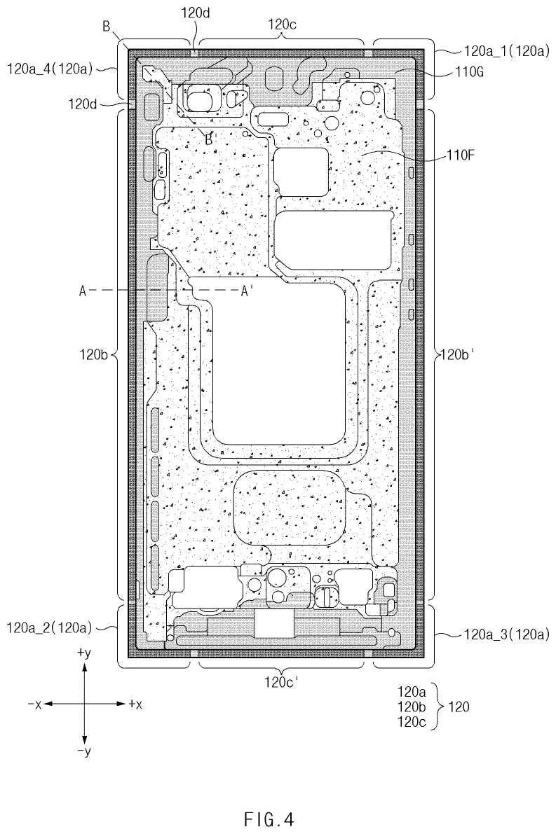

Referring to FIGS. 1A and 1B, in one embodiment, an electronic device 100 may include a housing 110 including a first surface (or front surface) 110A, a second surface (or rear surface) 110B, and a side surface 110C surrounding a space between the first surface 110A and the second surface 110B. In one embodiment, the housing may be a structure forming some of the first surface 110A, the second surface 110B, and the side surface 110C in FIG. 1A. According to an embodiment, the first surface 110A may be formed by a front plate 102 (e.g., a glass plate or a polymer plate including various coating layers) that is at least partially substantially transparent. The second surface 110B may be formed by a rear plate 111 that is substantially opaque. The rear plate 111 may be formed by, for example, coated or colored glass, ceramic, polymer, metal (e.g., aluminum, stainless steel (STS), or magnesium), or a combination of at least two of the above materials. The side surface 110C may be coupled with the front plate 102 and the rear plate 111, and may be formed by a side bezel structure (or “side member”) 150 that includes metal and/or polymer. In one embodiment, the rear plate 111 and the side bezel structure 150 (e.g., a frame 120 in FIG. 4) may be integrally formed, and may include the same material (e.g., a metal material such as aluminum) as each other.

In the illustrated embodiment, the front plate 102 may include two first regions 110D that are bent from the first surface 110A toward the rear plate 111 and extend seamlessly. For example, the two first regions 110D may be positioned at both ends of a long edge of the front plate 102. In the illustrated embodiment (see FIG. 1B), the rear plate 111 may include two second regions 110E that are bent from the second surface 110B toward the front plate 102 and extend seamlessly. The two second regions 110E may be positioned at both ends of a long edge of the rear plate 111. In one embodiment, the front plate 102 (or the rear plate 111) may include only one of the first regions 110D (or the second regions 110E). In one embodiment, the front plate 102 (or the rear plate 111) may not include some of the first regions 110D or the second regions 110E. In the embodiments, when viewed from the side surface 110C of the electronic device 100, the frame 120 may have a first thickness (or width) toward the side surface 110C where the first regions 110D or the second regions 110E as described above are not included, and may have a second thickness thinner than the first thickness toward the side surface 110C where the first regions 110D or the second regions 110E are included.

According to an embodiment, the electronic device 100 may include at least one from among a display 101, audio holes (e.g., a microphone hole 103, an external speaker hole 107, and a call receiver hole 114), sensor modules (e.g., a first sensor module 104, a fourth sensor module 116, and a third sensor module 119), camera modules (e.g., a first camera device 105, a second camera device 112, and a flash 113), key input devices 117, a light emitting device 106, and connector holes (e.g., a first connector hole 108 and a second connector hole 109). In one embodiment, the electronic device 100 may omit at least one of the components (e.g., the key input devices 117 or the light emitting device 106), and/or may additionally include other components.

The display 101 may be visually exposed such as, for example, through at least a portion of the front plate 102. In one embodiment, at least a portion of the display 101 may be visually exposed through the front plate 102 forming the first surface 110A and the first regions 110D of the side surface 110C. In one embodiment, an edge of the display 101 may be formed to correspond to an outer edge of the front plate 102 adjacent to the edge. In one embodiment, in order to expand an area where the display 101 is visually exposed, the distances between the outer edges of the display 101 and the outer edges of the front plate 102 may be formed to be substantially the same as each other.

In one embodiment, a recess or opening may be formed in a part of a screen display region of the display 101, and at least one from among an audio hole (e.g., the call receiver hole 114), a sensor module (e.g., the first sensor module 104), a camera module (e.g., the first camera device 105), and the light emitting device 106 aligned with the recess or opening may be included. In one embodiment, on the rear of the screen display region of the display 101, at least one from among an audio hole (e.g., the call receiver hole 114), a sensor module (e.g., the first sensor module 104), a camera module (e.g., the first camera device 105), a fingerprint sensor (e.g., the fourth sensor module 116), and the light emitting device 106 may be included. In one embodiment, the display 101 may be coupled with or disposed adjacent to a touch sensing circuit, a pressure sensor capable of measuring the intensity (e.g., pressure) of the touch, and/or a digitizer detecting a magnetic field type stylus pen. In one embodiment, at least some of the sensor modules (e.g., the first sensor module 104, the fourth sensor module 116, and the third sensor module 119), and/or at least some of the key input devices 117 may be disposed at (e.g., in or on) the first regions 110D and/or the second regions 110E.

The audio holes may include a microphone hole 103 and speaker holes (e.g., an external speaker hole 107 and a call receiver hole 114). The microphone hole 103 may have a microphone for acquiring external sound disposed therein, and in one embodiment, a plurality of microphones may be disposed to detect the direction of sound. The speaker holes may include an external speaker hole 107 and a call receiver hole 114. In one embodiment, the speaker holes (e.g., the external speaker hole 107 and the call receiver hole 114) and the microphone hole 103 may be implemented as one hole, or a speaker may be implemented without the speaker holes (e.g., the external speaker hole 107 and the call receiver hole 114) (e.g., a piezo speaker).

The sensor modules (e.g., the first sensor module 104, a second sensor module, the fourth sensor module 116, and the third sensor module 119) may generate an electrical signal or data value corresponding to an internal operational state or an external environmental state of the electronic device 100. The sensor modules may include, for example, a first sensor module 104 (e.g., a proximity sensor) and/or a second sensor module (e.g., a fingerprint sensor) disposed at the first surface 110A of the housing 110, and/or a third sensor module 119 (e.g., a heart rate motor (HRM) sensor) and/or a fourth sensor module 116 (e.g., a fingerprint sensor) disposed at the second surface 110B of the housing 110. The fingerprint sensor may be disposed at the second surface 110B as well as the first surface 110A (e.g., the display 101) of the housing 110. The electronic device 100 may further include a sensor module such as, for example, at least one from among a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, and an illuminance sensor (e.g., the first sensor module 104).

The camera modules may include the first camera device 105 disposed at the first surface 110A of the electronic device 100, and a second camera device 112 disposed at the second surface 110B, and/or a flash 113. The camera devices (e.g., the first camera device 105 and the second camera device 112) may include one or more lenses, an image sensor, and/or an image signal processor. The flash 113 may include, for example, a light emitting diode or a xenon lamp. In one embodiment, two or more lenses (e.g., infrared camera lenses, wide-angle lenses, and telephoto lenses) and image sensors may be disposed at one surface of the electronic device 100.

The key input devices 117 may be disposed at the side surface 110C of the housing 110. In one embodiment, the electronic device 100 may not include some or all of the key input devices 117 mentioned above, and the key input device(s) 117, which is (are) not included, may be implemented in other forms, such as a soft key, on the display 101. In one embodiment, the key input device 117 may include a sensor module (e.g., the fourth sensor module 116) disposed at the second surface 110B of the housing 110.

The light emitting device 106 may be disposed at, for example, the first surface 110A of the housing 110. The light emitting device 106 may provide, for example, state information about the electronic device 100 in the form of light. In one embodiment, the light emitting device 106 may provide, for example, a light source in conjunction with the operation of the camera module (e.g., the first camera device 105). The light emitting device 106 may include, for example, a light emitting diode (LED), an infrared (IR) LED, and a xenon lamp.

The connector holes may include a first connector hole 108 capable of accommodating a connector (e.g., a universal serial bus (USB) connector) for transmitting and receiving electric power and/or data to and from an external electronic device, and/or a second connector hole 109 (e.g., an earphone jack) capable of accommodating a connector for transmitting and receiving audio signals to and from an external electronic device. In one example, the second connector hole 109 may be omitted from the electronic device 100.

Referring to FIG. 1C, in one embodiment, the electronic device 100 may include a frame 120, a first support member 110F (e.g., a bracket), the front plate 102 (e.g., a cover window or a cover plate), the display 101, a first printed circuit board 110H, a battery 110J, a second printed circuit board 110L, an antenna structure 110K, and the rear plate 111 (e.g., a rear case). In one embodiment, the electronic device 100 may omit at least one from among the components (e.g., the first support member 110F or the second printed circuit board 110L), and/or may additionally include other components. At least one of the components of the electronic device 100 may be the same as or similar to at least one of the components of the electronic device 100 in FIG. 1A or 1B, and the description thereof may not be repeated below.

The first support member 110F may be disposed inside the electronic device 100 to be connected to the frame 120, or may be formed integrally with the frame 120. The first support member 110F may be formed of, for example, a metal material and/or a non-metal (e.g., polymer) material. The display 101 may be coupled to one surface of the first support member 110F, and the first printed circuit board 110H may be coupled to the other surface of the first support member 110F. The first printed circuit board 110H may be equipped with a processor, a memory, and/or an interface. The processor may include, for example, one or more from among a central processing unit, an application processor, a graphic processing unit, an image signal processor, a sensor hub processor, or a communication processor. The memory may include, for example, a volatile memory or a non-volatile memory. The interface may include, for example, a high definition multimedia interface (HDMI), a USB interface, a secure digital (SD) card interface, and/or an audio interface. The interface may electrically or physically connect the electronic device 100 to, for example, an external electronic device, and may include a USB connector, an SD card/MMC connector, or an audio connector.

The battery 110J may be a device for supplying electric power to at least one of the components of the electronic device 100, and may include, for example, a primary cell which is not rechargeable, a secondary cell which is rechargeable, or a fuel cell. At least a portion of the battery 110J may be disposed, for example, on substantially the same plane as the first printed circuit board 110H. The battery 110J may be integrally disposed inside the electronic device 100, or may be disposed to be detachable from the electronic device 100.

The antenna structure 110K may be disposed between the rear plate 111 and the battery 110J. The antenna structure 110K may include, for example, a near field communication (NFC) antenna, a wireless charging antenna, and/or a magnetic secure transmission (MST) antenna. The antenna structure 110K may, for example, perform short range communication with an external device, or may wirelessly transmit and receive electric power for charging. In one embodiment, the antenna structure may be formed by the frame 120 and/or a portion of the first support member 110F or a combination thereof.

In one embodiment, the configurations of FIGS. 1A to 1C and the descriptions provided for the configurations may be equally referenced for the same configurations of FIGS. 4 to 14B.

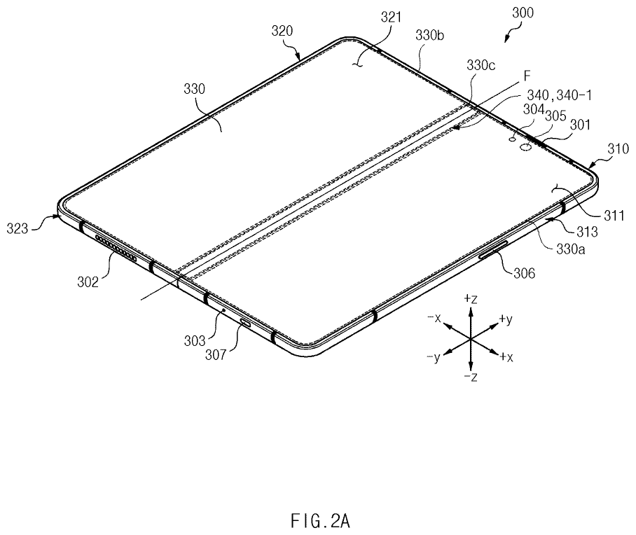

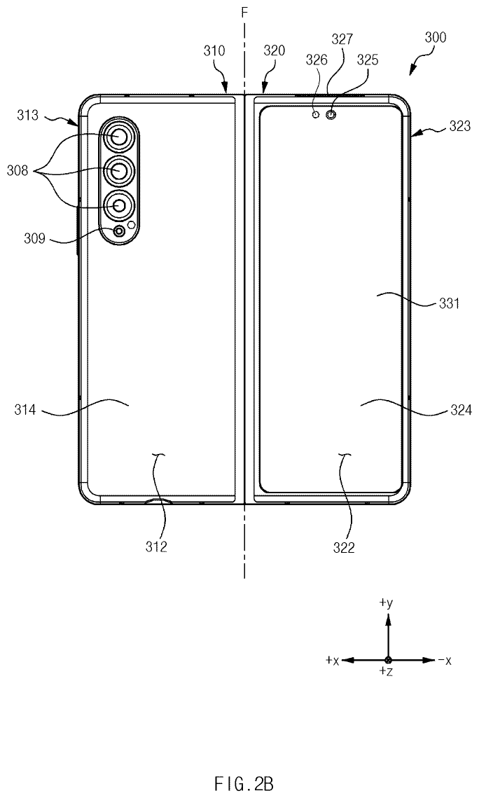

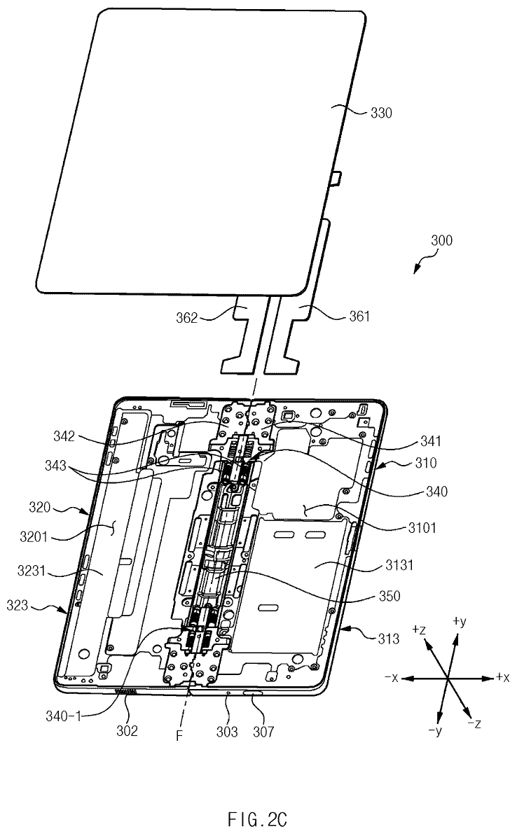

FIG. 2A is a front perspective view of an electronic device according to an embodiment.

FIG. 2B is a plan view illustrating a rear surface of an electronic device according to an embodiment.

Referring to FIGS. 2A and 2B, an electronic device 300 (e.g., a foldable electronic device) may include a first housing 310 (e.g., a first housing structure) including a first side member 313 (e.g., a side bezel), and a second housing 320 (e.g., a second housing structure) including a second side member 323 (e.g., a side bezel), which are coupled to be foldable with respect to each other by means of at least one hinge device 340 and/or 340-1 (e.g., a hinge module or a hinge structure), with respect to a folding axis F. For example, the first housing 310 and the second housing 320 may be configured as a foldable housing (e.g., a housing structure). For example, the electronic device 300 may include a first display 330 (e.g., a flexible display, a foldable display, or a main display) arranged to be supported by the first housing 310 and the second housing 320. For example, the first housing 310 may include a first surface 311 and a second surface 312 facing away from the first surface 311 (e.g., in the −z axis direction). For example, the second housing 320 may include a third surface 321 and a fourth surface 322 facing away from the third surface 321 (e.g., in the −z-axis direction). For example, the first housing 310 may include a first rear cover 314 coupled to the first side member 313. For example, the second housing 320 may include a second rear cover 324 coupled to a second side member 323. For example, when the electronic device 300 is in a fully unfolded first state (e.g., an unfolded state or an unfolding state), the first surface 311 and the third surface 321 may face substantially the same direction (e.g., the z-axis direction). For example, when the electronic device 300 is in a fully folded second state (e.g., a folded state or a folding state), the first surface 311 and the third surface 321 face each other or face the opposite directions. For example, the electronic device 300 may be operated to maintain a third state (e.g., an intermediate state) between the first state and the second state.

According to an embodiment, the electronic device 300 may include a first receiver 301 disposed through the first surface 311 of the first housing 310, at least one first sensor module 304 (e.g., an illuminance sensor), and/or at least one first camera module 305 (e.g., an under display camera (UDC)). For example, the electronic device 300 may include at least one key 306 disposed on the first side member 313. For example, the electronic device 300 may include at least one second camera module 308 and/or a flash 309 disposed through the second surface 312 (e.g., the first rear cover 314) of the first housing 310. For example, the electronic device 300 may include a second display 331 disposed on the fourth surface 322 of the second housing 320, at least one third camera module 325 (e.g., an under display camera (UDC)), at least one second sensor module 326, and/or a second receiver 327. For example, the second display 331 may be disposed to be visible from the outside through at least a portion of the second rear cover 324. For example, the electronic device 300 may include a speaker 302 disposed through the second side member 323, a microphone 303 disposed through the first side member 313, and/or a connector port 307. At least some of the above-described components may be disposed in the first housing 310 and/or the second housing 320.

According to an embodiment, the first display 330 (e.g., a flexible display) may include a first area 330a (e.g., a first flat portion) corresponding to at least a portion of the first surface 311, a second area 330b (e.g., a second flat portion) corresponding to at least a portion of the third surface 321, and a third area 330c (e.g., a flexible portion) that connects the first area 330a and the second area 330b, in which the electronic device 300 is deformed from the second state (e.g., a folding state) and/or the third state. For example, the third area 330c may be disposed at a position at least partially overlapping the at least one hinge device 340 or 340-1, when the first display 330 is viewed from above (e.g., in the z-axis direction). For example, in the second state, the first display 330 may be disposed such that the first surface 311 and the third surface 321 face each other and are not visible from the outside (e.g., an in-folding type). For example, in the second state, the first display 330 may be disposed such that the first surface 311 and the third surface 321 face the directions opposite to each other, thereby being visible from the outside (e.g., an out-folding type).

FIG. 2C is a partial exploded perspective view of an electronic device of FIGS. 2A and 2B including a hinge device according to an embodiment.

Referring to FIG. 2C, the electronic device 300 may include at least one hinge device 340 and 340-1 (e.g., a hinge module or a hinge structure) connecting the first housing 310 and the second housing 320 underneath the first display 330 (e.g., in the −z axis direction). For example, the at least one hinge device 340 and 340-1 may include a first hinge device 340 and a second hinge device 340-1 spaced apart from the first hinge device 340 along a direction (e.g., ±y-axis direction) parallel to the folding axis F. For example, the at least one hinge device 340 and/or 340-1 may be supported by a first support member 3131 extending from the first side member 313 to a first space 3101 of the first housing 310 and a second support member 3231 extending from the second side member 323 to a second space 3201 of the second housing 320. For example, the at least one hinge device 340 and/or 340-1 may be disposed between the first housing 310 and the second housing 320 so as not to be visible from the outside through the hinge housing 350 (e.g., a hinge cover).

According to an embodiment, the first hinge device 340 may include a first rotation member 341 (e.g., a first arm or a first rotator) disposed on the first support member 3131 of the first housing 310, a second rotation member 342 (e.g., a second arm or a second rotator) disposed on the second support member 3231 of the second housing 320, and a gear assembly 343 connecting the first rotation member 341 and the second rotation member 342 and coupling the first housing 310 and the second housing 320 to rotate symmetrically with respect to each other. For example, the gear assembly 343 may include a plurality of gears (e.g., spur gears and/or worm gears) meshed with respect to each other. For example, the gear assembly 343 may include a cam coupling structure configured to pressurize the first housing 310 and the second housing 320 in a direction to be shifted from the first state (e.g., an unfolded state or an unfolding state) to the second state (e.g., a folded state or a folding state) or a direction to be shifted from the second state to the first state, relative to a certain angle to each other, and to provide a sense of stopping at various folding angles. For example, the second hinge device 340-1 may have substantially the same configuration as the first hinge device 340.

According to an embodiment, the electronic device 300 may include a first hinge plate 361 connected to a first support member 3131 and/or a first rotation member 341. The electronic device 300 may include a second hinge plate 362 connected to a second support member 3231 and/or a second rotation member 342. For example, the at least one hinge device 340 and/or 340-1, the first rotation member 341, the second rotation member 342, the first hinge plate 361, and the second hinge plate 362 may form substantially the same plane as the first support member 3131 and the second support member 3231, when the electronic device 300 is in the first state. For example, the second hinge device 340-1 may be substantially symmetrical to the first hinge device 340 or may have substantially the same configuration.

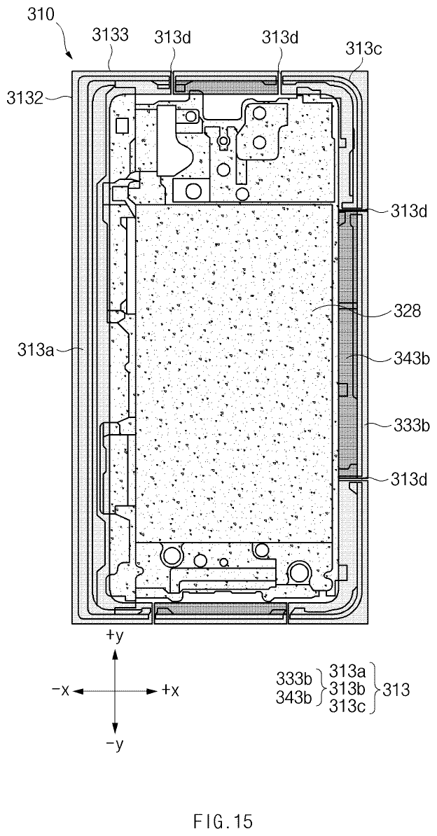

According to an embodiment, the configurations of FIGS. 2A to 2C and the descriptions provided for the configurations may be equally referenced to the same configurations of FIG. 15.

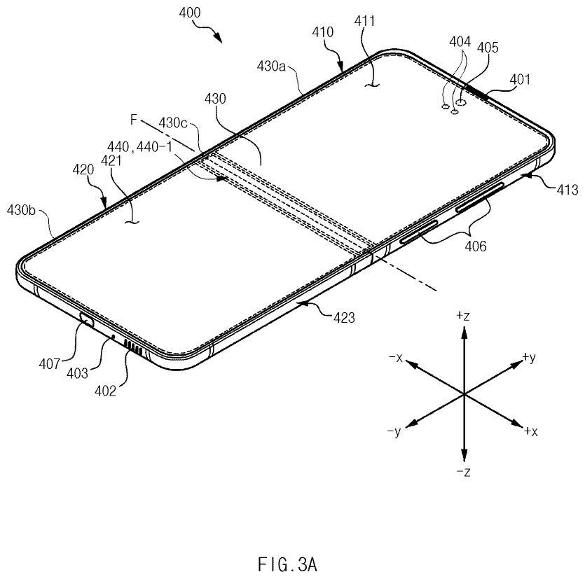

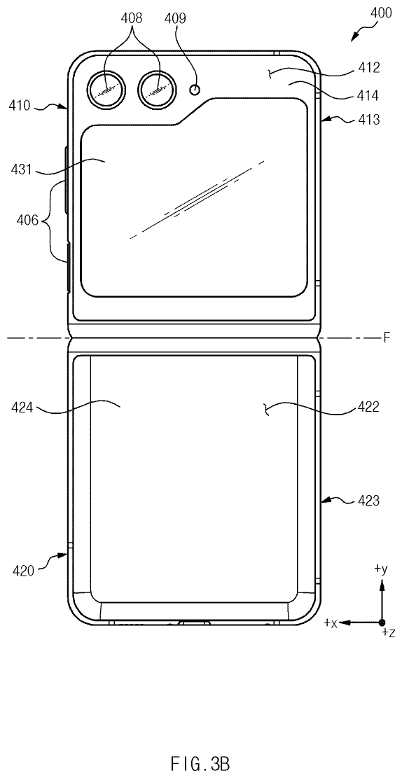

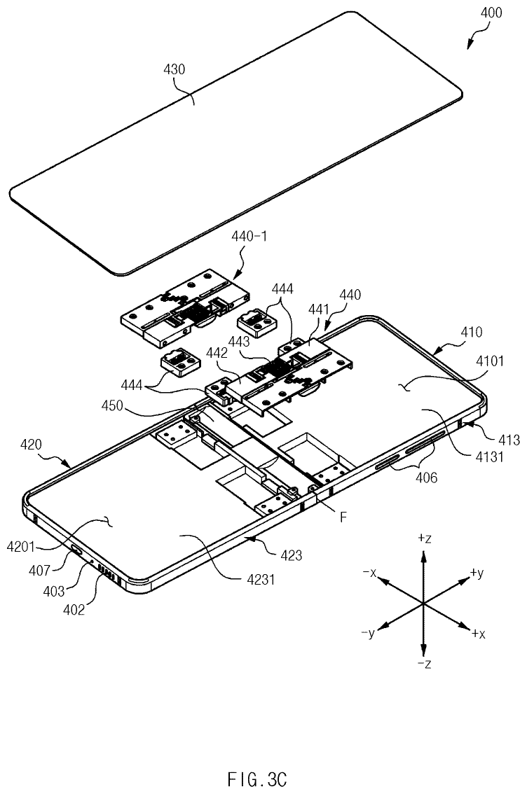

FIG. 3A is a front perspective view of an electronic device according to an embodiment.

FIG. 3B is a plan view illustrating a rear surface of an electronic device according to an embodiment.

Referring to FIGS. 3A and 3B, an electronic device 400 (e.g., a foldable electronic device) may include a first housing 410 (e.g., a first housing structure) including a first side member 413 (e.g., a side bezel) and a second housing 420 (e.g., a second housing structure) having a second side member 423 (e.g., a side bezel), which are coupled to be foldable with respect to each other by means of at least one hinge device 440 and/or 440-1 (e.g., a hinge module or a hinge structure) with respect to a folding axis F. For example, the first housing 410 and the second housing 420 may be configured as a foldable housing (e.g., a housing structure). For example, the electronic device 400 may include a first display 430 (e.g., a flexible display, a foldable display, or a main display) disposed to be supported by the first housing 410 and the second housing 420. For example, the first housing 410 may include a first surface 411 and a second surface 412 facing away from the first surface 411 (e.g., the −z axis direction). For example, the second housing 420 may include a third surface 421 and a fourth surface 422 facing away from the third surface 421 (e.g., the −z-axis direction). For example, the first housing 410 may include a first rear cover 414 coupled to the first side member 413. For example, the second housing 420 may include a second rear cover 424 coupled to the second side member 423. For example, when the electronic device 400 is in a fully unfolded first state (e.g., an unfolded state or an unfolding state), the first surface 411 and the third surface 421 may face substantially the same direction (e.g., the z-axis direction). For example, when the electronic device 400 is in a fully folded second state (e.g., a folded state or a folding state), the first surface 411 and the third surface 421 may face each other or face the opposite directions. For example, the electronic device 400 may be operated to maintain a third state (e.g., an intermediate state) between the first state and the second state.

According to an embodiment, the electronic device 400 may include a receiver 401, at least one sensor module 404 (e.g., an illuminance sensor), and/or at least one first camera module 405 (e.g., an under display camera (UDC)) that are disposed through the first surface 411 of the first housing 410. For example, the electronic device 400 may include at least one key 406 disposed on the first side member 413. For example, the electronic device 400 may include a second display 431 (e.g., a sub-display), at least one second camera module 408, and/or a flash 409 that are disposed through the second surface 412 (e.g., the first rear cover 414) of the first housing 410. For example, the second display 431 may be disposed to be visible from the outside through at least a portion of the first rear cover 414. For example, the electronic device 400 may include a speaker 402, a microphone 403, or a connector port 407 that are disposed through the second side member 423. An arrangement of at least some of the above-described plurality of components may be changed to be disposed in the first housing 410 and/or the second housing 420.

According to an embodiment, the first display 430 (e.g., a flexible display) may include a first area 430a (e.g., a first flat portion) corresponding to at least a portion of the first surface 411, a second area 430b (e.g., a second flat portion) corresponding to at least a portion of the third surface 421), and a third area 430c (e.g., a flexible portion) that connects the first area 430a and the second area 430b, in which the electronic device 400 is deformed in the second state (e.g., a folding state) and/or the third state (e.g., an intermediate state). For example, the third area 430c may be disposed at a position at least partially overlapping the at least one hinge device 440 or 440-1, when the first display 430 is viewed from above (e.g., in the z-axis direction). For example, in the second state, the first display 430 may be disposed such that the first surface 411 and the third surface 421 face each other, thereby being not visible from the outside (e.g., an in-folding type). For example, in the second state, the first display 430 may be disposed such that the first surface 411 and the third surface 421 face the directions opposite to each other, thereby being visible from the outside (e.g., an out-folding type).

FIG. 3c is a partial exploded perspective view of the electronic device of FIGS. 3A and 3B including a hinge device according to an embodiment.

Referring to FIG. 3c, an electronic device 400 may include at least one hinge device 440 and/or 440-1 (e.g., a hinge module or a hinge structure) connecting the first housing 410 and the second housing 420 underneath the first display 430 (e.g., in the −z axis direction). For example, the at least one hinge device 440 and/or 440-1 may include a first hinge device 440 and a second hinge device 440-1 spaced apart from the first hinge device 440 in a direction (e.g., ±y-axis direction) parallel to the folding axis F. For example, the at least one hinge device 440 and/or 440-1 may be supported by a first support member 4131 extending from the first side member 413 to a first space 4101 of the first housing 410, and a second support member 4231 extending from the second side member 423 to a second space 4201 of the second housing 420. For example, the at least one hinge device 440 and/or 440-1 may be disposed between the first housing 410 and the second housing 420 so as not to be visible from the outside through the hinge housing 450 (e.g., a hinge cover).

According to an embodiment, the first hinge device 440 may include a first rotation member 441 (e.g., a first arm or a first rotator) disposed on the first support member 4131 of the first housing 410, a second rotation member 442 (e.g., a second arm or a second rotator) disposed on the second support member 4231 of the second housing 420, and a gear assembly 443 connecting the first rotation member 441 and the second rotation member 442 and coupling the first housing 410 and the second housing 420 to rotate symmetrically with respect to each other. For example, the gear assembly 443 may include a plurality of gears (e.g., spur gears and/or worm gears) meshed with each other. For example, the gear assembly 443 may include a cam coupling structure configured to pressurize the first housing 410 and the second housing 420 in a direction to be shifted from the first state (e.g., an unfolded state or an unfolding state) to the second state (e.g., a folded state or a folding state) or a direction to be shifted from the second state to the first state, relative to a certain angle to each other, and to provide a sense of stopping at various folding angles. For example, the second hinge device 440-1 may have substantially the same configuration as the first hinge device 440.

According to an embodiment, the electronic device 400 may include at least one detent module 444 interlocking with the at least one hinge device 440 and/or 440-1 and providing a sense of stopping at various angles. For example, the at least one hinge device 440 and/or 440-1 and/or the detent module 444 may form substantially the same plane as the first support member 4131 and the second support member 4231, when the electronic device 400 is in the first state. For example, the second hinge device 440-1 may be substantially symmetrical to the first hinge device 440 or may have substantially the same configuration as each other.

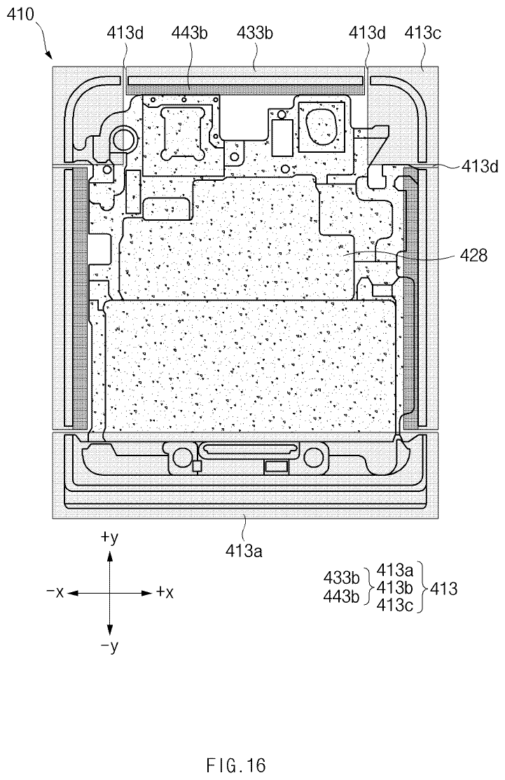

According to an embodiment, the configurations of FIGS. 3A to 3c and the descriptions provided for the configurations may be equally referenced to the same configurations of FIG. 16.

FIG. 4 is view schematically illustrating a form of the frame of the electronic device according to an embodiment.

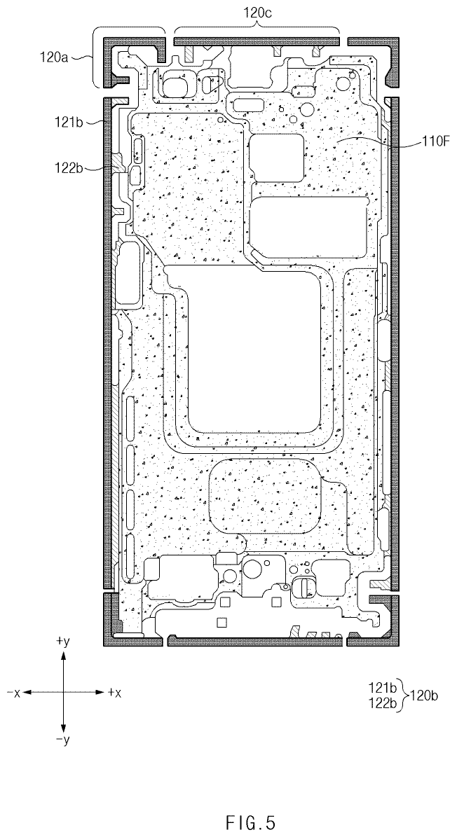

FIG. 5 is a view schematically illustrating the form of the frame of the electronic device according to an embodiment, excluding an injection-molded material.

FIG. 4 is a view illustrating the form of the frame 120 in which both the first support member 110F and a second support member 110G are coupled to the frame 120. FIG. 5 is a view illustrating a form in which only the first support member 110F is coupled to the frame 120.

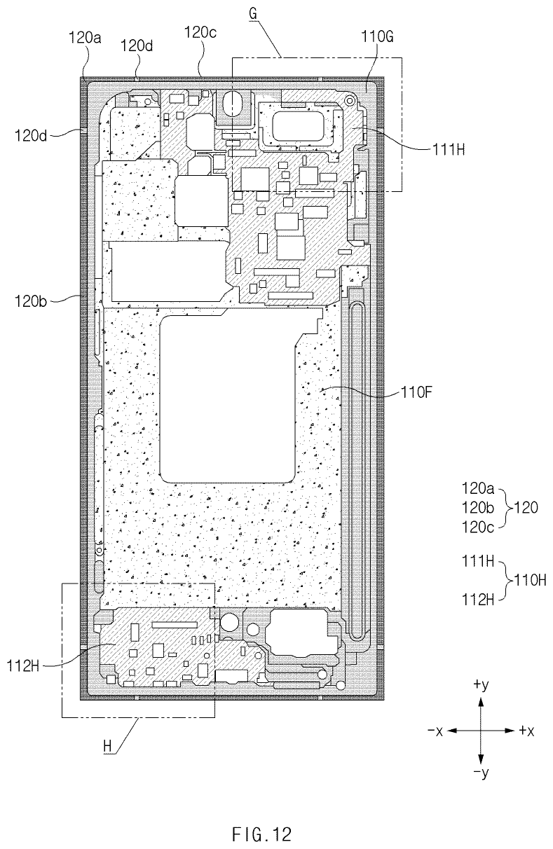

Referring to FIGS. 1A to 1C, FIG. 4, and FIG. 5, in one embodiment, the electronic device 100 may include the housing 110. The housing 110 may include the first surface 110A (e.g., a front surface), the second surface 110B (e.g., a rear surface), the side surface 110C surrounding a space between the first surface 110A and the second surface 110B, the first support member 110F and a printed circuit board (e.g., the first printed circuit board 110H in FIG. 12) disposed in the space, and the second support member 110G joining the side surface 110C and the first support member 110F.

The side surface 110C may include the frame 120 (e.g., the side bezel structure 150 in FIG. 1C). In one embodiment, the frame 120 may include a corner portion 120a, a first side portion 120b, and a second side portion 120c, all of which form at least a portion of the side surface 110C. The corner portion 120a may be formed in a part of a region where two edges of the side surface 110C meet. The first side portion 120b may be formed spaced apart from the corner portion 120a in a first direction (e.g., in a −y-axis direction), and the second side portion 120c may be formed spaced apart from the corner portion 120a in a second direction (e.g., in a +x-axis direction) perpendicular to the first direction.

In one embodiment, when the frame 120 is formed in a rectangular shape (or has four edges), the frame 120 may include four different corner portions. As one example, a plurality of the corner portion 120a may be provided and include four different corner portions, including portions extending in the x-axis direction and portions extending in the y-axis direction. For example, when the frame 120 is viewed from above (e.g., when viewed in the +z-axis direction), the frame 120 may include a corner portion 120a-4 formed at an upper left, a corner portion 120a_1 formed at an upper right, a corner portion 120a_2 formed at a lower left, and a corner portion 120a_3 formed at a lower right.

In one embodiment, when the frame 120 is formed in a rectangular shape (or has four edges), the frame 120 may include a first side portion 120b, a second side portion 120c, a third side portion 120b′ formed opposite the first side portion 120b, and a fourth side portion 120c′ formed opposite the second side portion 120c. As one example, when the frame 120 is viewed from above (e.g., when viewed in the +z-axis direction), the first side portion 120b may form at least a portion of a left region of the frame 120, and the second side portion 120c may form at least a portion of an upper region of the frame 120. In addition, as one example, the third side portion 120b′ may form at least a portion of a right region of the frame 120, and the fourth side portion 120c′ may form at least a portion of a lower region of the frame 120. In one embodiment, the corner portions may each include a bending portion formed to have at least one specified curvature. The bending portion may be formed to have a curvature within a range of several mm (e.g., 0.5 mm to 8 mm).

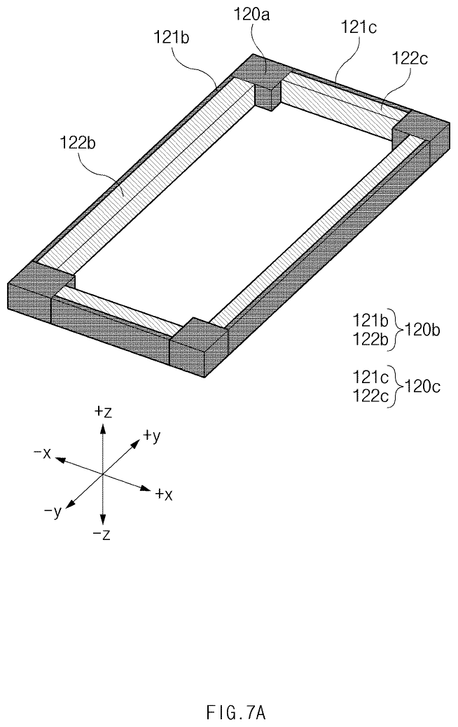

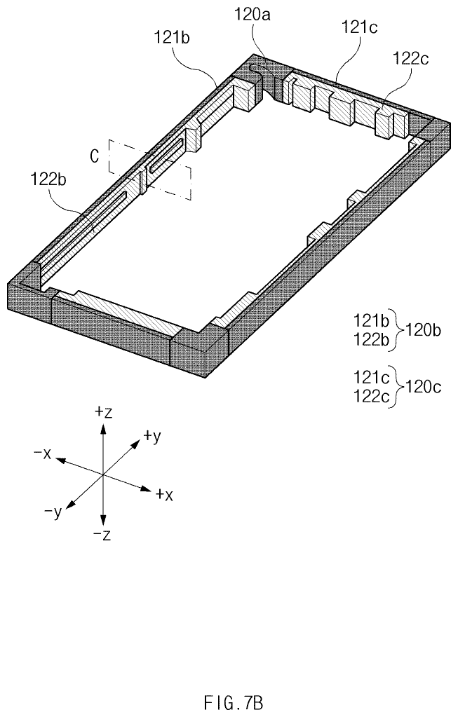

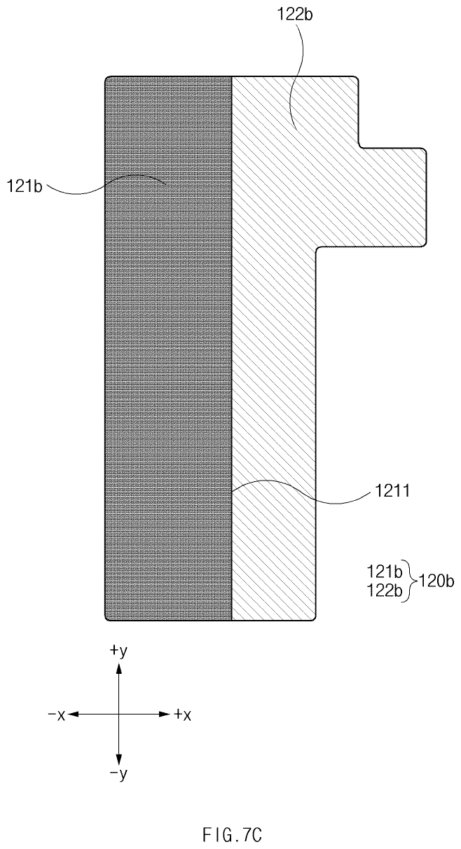

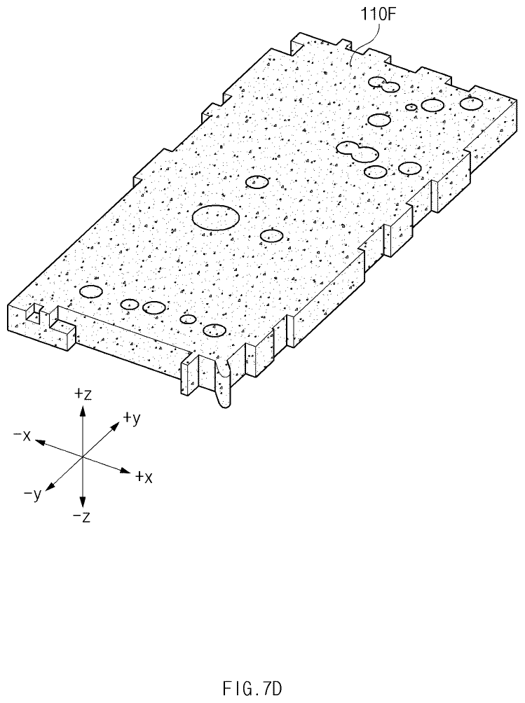

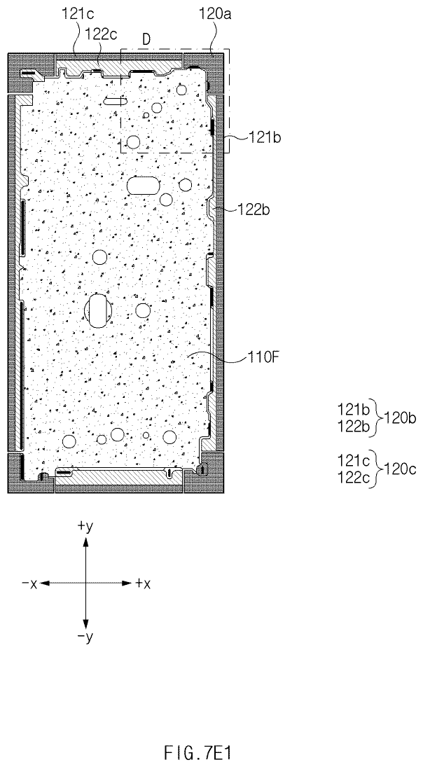

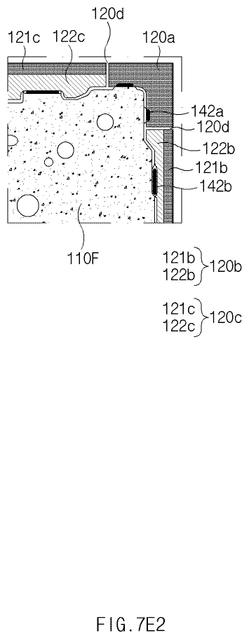

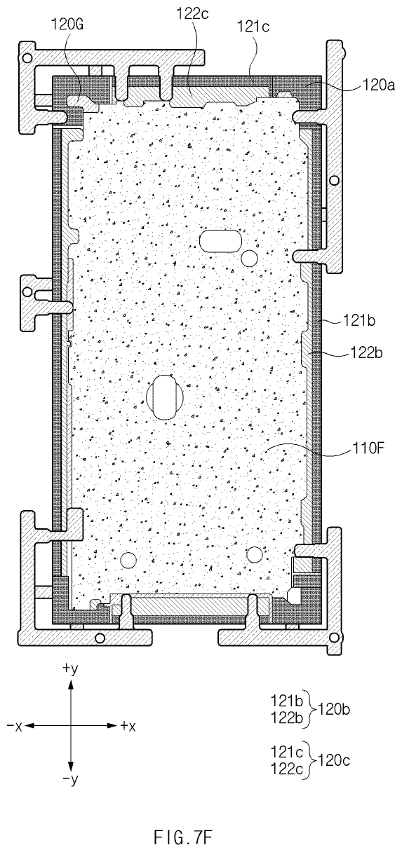

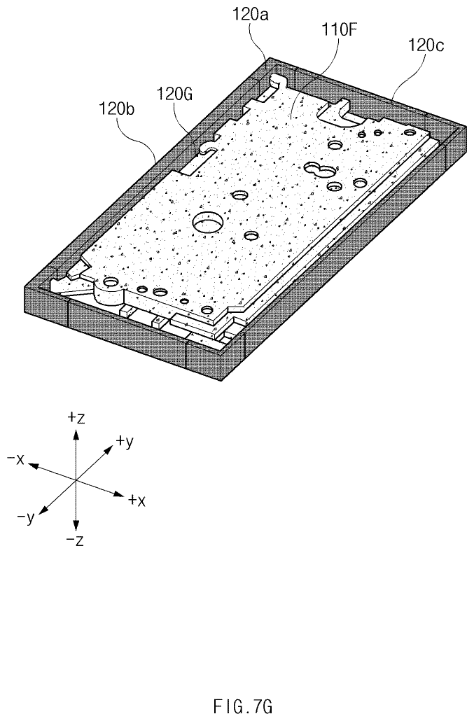

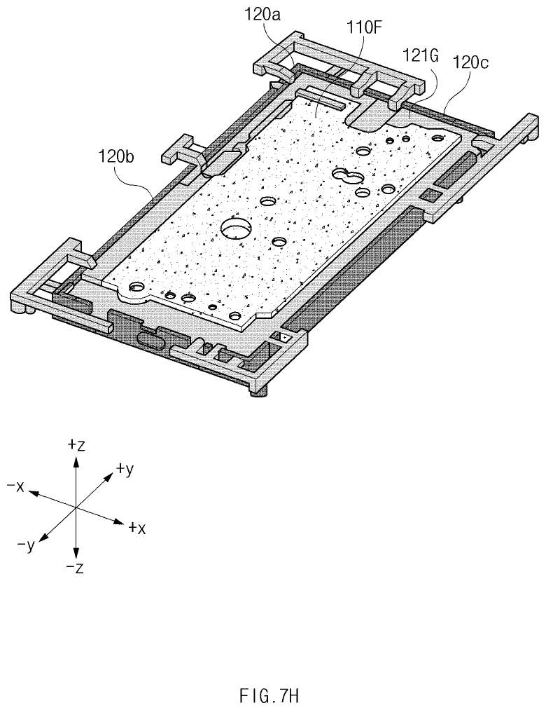

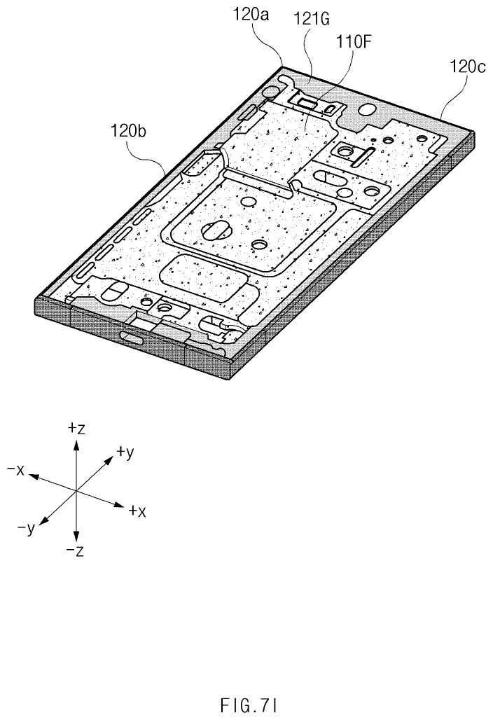

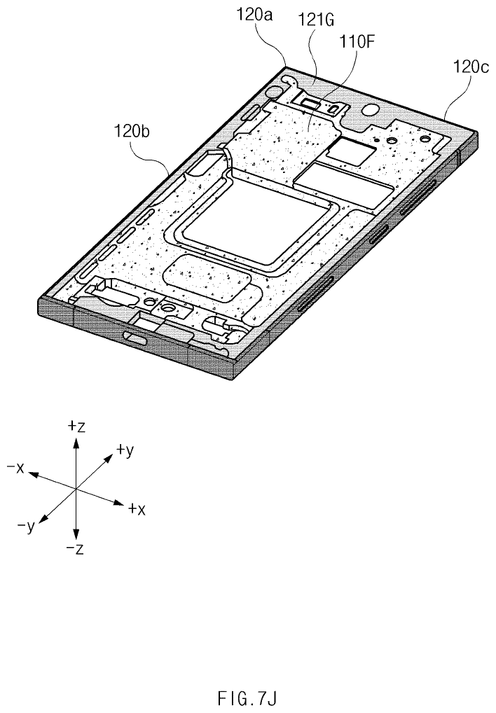

The frame 120 may be formed from a metal material. In one embodiment, the frame 120 may be formed from a first metal (e.g., titanium) and a second metal (e.g., aluminum). In one embodiment, the corner portions 120a may be formed of the first metal. For example, the corner portion 120a may be formed only of the first metal. For example, the corner portion 120a may not include a clad metal in which a dissimilar metal (e.g., the second metal) is coupled to the first metal. For example, the corner portion 120a may be formed without including a clad structure. In one embodiment, the first side portion 120b may include a first outer portion 121b formed of the first metal, and a first inner portion 122b formed of the second metal. For example, the first side portion 120b may be formed by coupling the first outer portion 121b formed of the first metal and the first inner portion 122b formed of the second metal. The first outer portion 121b may be disposed on an outwardly facing surface of the housing 110 (e.g., a surface facing the −x-axis direction) to form a portion of the side surface 110C. The first inner portion 122b may be disposed on a surface (e.g., an inner surface of the first outer portion 121b) facing the inside of the housing 110 (e.g., a surface facing the +x-axis direction). In one embodiment, the first side portion 120b may include a clad metal in which the first outer portion 121b and the first inner portion 122b are coupled. For example, the first side portion 120b may include the clad metal in which the first metal (e.g., titanium) and the second metal (e.g., aluminum) are coupled. In one embodiment, the second side portion 120c may be formed with substantially the same structure (e.g., a clad structure) as the first side portion 120b. For example, the second side portion 120c may include a clad metal in which a second outer portion (e.g., a second outer portion 121c in FIG. 7a) disposed on a surface facing the outside of the housing 110 (e.g., a surface facing the +y-axis) and a second inner portion (e.g., a second inner portion 122c in FIG. 7a) disposed on a surface (e.g., an inner surface of the second outer portion) facing the inside of the housing 110 (e.g., a surface facing the −y-axis) are coupled. In one embodiment, the third side portion 120b′ and/or the fourth side portion 120c′ may be formed with substantially the same structure (e.g., a clad structure) as the first side portion 120b. With regard to the clad metal (or clad structure), a more detailed description will be given below with reference to FIGS. 7A and 7B.

In one embodiment, gaps 120d may be formed in a region other than the region formed as the frame 120 of the side surface 110C. For example, a gap 120d may be formed between the corner portion 120a and the first side portion 120b, and a gap 120d may be formed between the corner portion 120a and the second side portion 120c. For example, the frame 120 may have a form in which the first side portion 120b, the corner portion 120a, and the second side portion 120c are separated at regular intervals (e.g., the gaps 120d). Alternatively, for example, the frame 120 may include a structure in which the first side portion 120b, the corner portion 120a (e.g., an upper left corner portion), the second side portion 120c, the corner portion 120a_1 (e.g., an upper right corner portion), the third side portion 120b′, the corner portion 120a_3 (e.g., a lower right corner portion), the fourth side portion 120c′, and the corner portion 120a_2 (e.g., a lower left corner portion) are spaced apart at regular intervals (e.g., the gaps 120d). Accordingly, when the frame 120 is formed of metal, at least one from among the corner portions 120a_1, 120a_2, 120a_3, and 120a_4, the first side portion 120b, the second side portion 120c, the third side portion 120b′, and the fourth side portion 120c′ may be used as an antenna radiator as a conductive segment. In one embodiment, the gaps 120d may be filled by an injection-molded material (or non-conductive member) (e.g., the second support member 110G). This will be described in detail below with reference to FIGS. 7H, 8, and 9. For example, the gap 120d may be an insulating portion. In one embodiment, the third side portion 120b′ may be made of substantially the same metal in substantially the same process as the first side portion 120b, and the fourth side portion 120c′ may be made of substantially the same metal in substantially the same process as the second side portion 120c. Therefore, for convenience of description, the following description will focus on the first side portion 120b and the second side portion 120c. However, the shape and/or material of the third side portion 120b′ and the fourth side portion 120c′ are not necessarily limited to the shape and/or material of the first side portion 120b and the second side portion 120c, and the shape and/or material of the third side portion 120b′ and the fourth side portion 120c′ may be formed differently from the first side portion 120b and the second side portion 120c.

The first support member 110F may be disposed in an internal space of the housing 110 (e.g., an internal space of the frame 120). The first support member 110F may be formed to support various components of the electronic device 100 (e.g., the display 101 or the printed circuit board (e.g., the first printed circuit board 110H in FIG. 12)). In one embodiment, the first support member 110F may be formed to be physically and/or electrically connected to the frame 120. In this way, at least a portion of the frame 120 (e.g., the corner portion 120a, the first side portion 120b, or the second side portion 120c) may be electrically connected to the first printed circuit board 110H. In one embodiment, the first support member 110F may be formed from the second metal. For example, the second metal may be aluminum or an aluminum alloy. Alternatively, in one embodiment, the first support member 110F may be formed from a third metal. For example, the first support member 110F may be formed of a metal different from the first metal and the second metal forming a part of the frame 120. For example, the first support member 110F may include a metal different from the second metal forming the first inner portion 122b.

The second support member 110G may be coupled to the first support member 110F and the frame 120. In one embodiment, the second support member 110G may include a second-first support member (e.g., a second-first support member 120G in FIG. 7F) coupled to the first support member 110F and the first inner portion 122b, and a second-second support member (e.g., a second-second support member 121G in FIG. 7H) coupled to the first support member 110F and the corner portion 120a. In one embodiment, the second support member 110G may be an injection-molded material formed by insert injection molding. In one embodiment, the second support member 110G may be formed of a non-conductive member. This will be described in detail below with reference to FIGS. 7F and 7H.

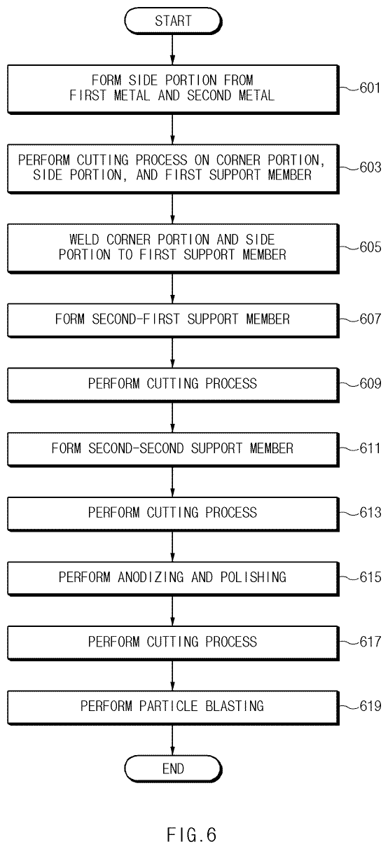

FIG. 6 is a view for describing a manufacturing and coupling process for a frame of an electronic device according to an embodiment.

FIGS. 7A to 7J are views schematically illustrating the manufacturing and coupling process for a frame of an electronic device according to an embodiment.

FIG. 7A is a view illustrating the form of a frame (e.g., the frame 120 in FIG. 4) before a cutting process (e.g., computer numerical control (CNC) process). FIG. 7B is a view illustrating the form of a frame (e.g., frame 120 in FIG. 4) after the cutting process. FIG. 7C is a view schematically illustrating a clad structure of the frame 120. FIG. 7C is a view illustrating the form of a region C in FIG. 7B as viewed in the +y-axis direction. FIG. 7D is a view illustrating the form of the support member (e.g., the first support member 110F in FIG. 4) after the cutting process.

Referring to FIGS. 1A to 1C, FIGS. 4 to 6, FIG. 7A, FIG. 7B, FIG. 7C, and FIG. 7D, in one embodiment, in operation 601 of FIG. 6, at least a portion of the frame 120 (e.g., the corner portion 120a, the first side portion 120b, the second side portion 120c, the third side portion 120b′, and/or the fourth side portion 120c′) may be formed. Alternatively, in one embodiment, in operation 601 of FIG. 6, the corner portion(s) (e.g., the corner portion 120a), the first side portion 120b, the second side portion 120c, the third side portion 120b′, and the fourth side portion 120c′ may be formed. In one example, the first side portion 120b may be formed from the first metal (e.g., titanium) and the second metal (e.g., aluminum). The first outer portion 121b may be formed of the first metal, and the first inner portion 122b may be formed of the second metal. The first outer portion 121b and the first inner portion 122b may be coupled to form the first side portion 120b as one body. As one example, the first outer portion 121b and the first inner portion 122b may be formed of clad metal. For example, the first metal forming the first outer portion 121b and the second metal forming the first inner portion 122b may be mechanically coupled through rolling. In this process, a coupling interface 1211 (see FIG. 7C) formed between the first outer portion 121b and the first inner portion 122b may be formed to be flat (e.g., coupling surfaces of the first outer portion 121b and the first inner portion 122b are flat) compared to a case where the first outer portion 121b and the first inner portion 122b are coupled through another process (e.g., laser hatching followed by die casting). As one example, when the first side portion 120b formed of clad metal is observed with the naked eye, the coupling interface 1211 may be observed as flat, rather than undulating. In one embodiment, the first metal forming the first outer portion 121b may include a titanium alloy of a high strength grade (e.g., Grade 4 or Grade 5). In one embodiment, the second metal forming the first inner portion 122b may include a 6000 series aluminum alloy (e.g., aluminum-magnesium-silicon alloy) that is easy to form a clad metal with the first metal (e.g., titanium).

In one embodiment, at least a portion of the frame 120 (e.g., the second side portion 120c, the third side portion 120b′, and/or the fourth side portion 120c′) may be formed with substantially the same structure as the first side portion 120b. For example, the second side portion 120c may include a second outer portion 121c formed of the first metal (e.g., titanium) and a second inner portion 122c formed of the second metal (e.g., aluminum). The second outer portion 121c and the second inner portion 122c may be formed of clad metal and form the second side portion 120c as one body.

In one embodiment, in operation 603 of FIG. 6, a cutting process of the frame 120 and the first support member 110F may be performed. The cutting process of each of the frame 120 and the first support member 110F may be performed simultaneously or sequentially. The frame 120 and the first support member 110F after undergoing cutting process may be formed in a corresponding form (e.g., a form that may be interlocked with each other) so that they may be coupled to each other. That is, a cutting process (e.g., computer numerical control (CNC) process) may be performed to couple (or join) the frame 120 and the first support member 110F.

In one embodiment, a surface of the frame 120 facing the interior space of the housing 110 may be cut. For example, the inner portion of the corner portion 120a (e.g., a portion positioned in the opposite direction to a portion forming a portion of the side surface 110C of the corner portion 120a), the first inner portion 122b of the first side portion 120b, and the second inner portion 122c of the second side portion 120c may be cut. For example, in the corner portion 120a, the portion formed of the first metal (e.g., titanium) may be cut, while in the first side portion 120b and the second side portion 120c, the portion formed of the second metal (e.g., aluminum) may be cut. In this case, the portion formed of the first metal in the first side portion 120b and the second side portion 120c may not be cut. Accordingly, the time required for cutting the portion formed of the first metal may be reduced in the time required for the entire process (e.g., the time required to perform operations 601 to 619 of FIG. 6).

FIG. 7E1 is a view illustrating a form in which a frame (e.g., the frame 120 in FIG. 4) and the first support member (e.g., the first support member 110F in FIG. 4) are welded after cutting. FIG. 7E2 is an enlarged view of a region D of FIG. 7E1.

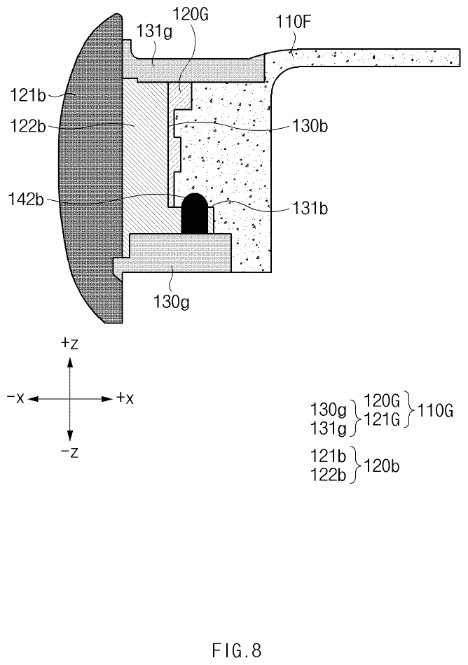

Referring to FIGS. 1A to 1C, FIGS. 4 to 7D, and FIGS. 7E1 and 7E2, in one embodiment, in operation 605 of FIG. 6, the frame 120 and the first support member 110F may be coupled to each other by welding. The corner portion 120a, the first side portion 120b, and the second side portion 120c may each be welded to the first support member 110F. In one embodiment, the first inner portion 122b of the first side portion 120b and the first support member 110F may be coupled through a first welding portion 142b (e.g., a connecting portion). In addition, the corner portion 120a and the first support member 110F may be coupled through a second welding portion 142a (e.g., a connecting portion). Accordingly, the first welding portion 142b may couple the second metal (e.g., aluminum) forming the first inner portion 122b and the second metal (e.g., aluminum) forming the first support member 110F. In addition, the second welding portion 142a may couple the first metal (e.g., titanium) forming the corner portion 120a and the second metal (e.g., aluminum) forming the first support member 110F. In one embodiment, the first welding portion 142b and the second welding portion 142a may be formed by laser welding. As one example, the first welding portion 142b and the second welding portion 142a may be formed by a continuous wave (CW) laser or a pulse laser. In this case, since the second welding portion 142a corresponds to a welding portion between dissimilar metals (e.g., the first metal and the second metal), the welding portion may be formed by the pulse laser. When the second welding portion 142a is formed by the pulse laser, a heat affected zone of the first support member 110F or the corner portion 120a adjacent to the second welding portion 142a may be reduced. Formation positions of the first welding portion 142b and the second welding portion 142a are described in detail below with reference to FIG. 8.

In one embodiment, the “coupling” of the frame 120 and the first support member 110F through the first welding portion 142b and the second welding portion 142a may refer to a physical connection and/or electrical connection between the frame 120 and the first support member 110F. For example, the frame 120 and the first support member 110F may be electrically connected by the first welding portion 142b and the second welding portion 142a, and then physically connected by the formation of the second support member 110G.

FIG. 7F is a view illustrating a form in which a frame (e.g., the frame 120 in FIG. 4) and the first support member (e.g., the first support member 110F in FIG. 4) are welded, and then the second support member (e.g., the second support member 110G in FIG. 4) is injection-molded into the space between the frame 120 and the first support member 110F.

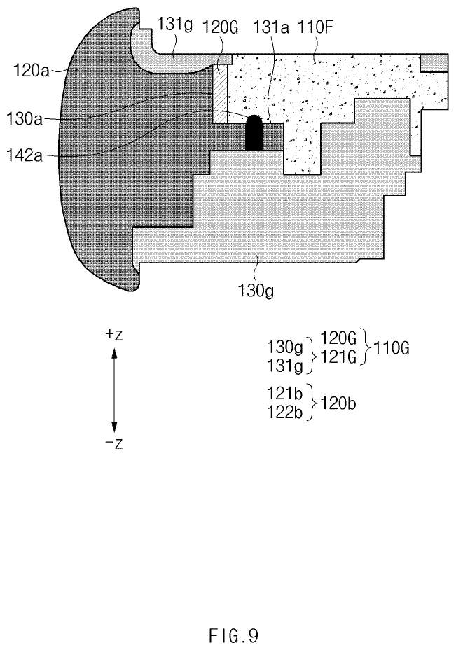

Referring to FIGS. 1A to 1C, FIGS. 4 to 7E2, and FIG. 7F, in one embodiment, a second-first support member 120G may be formed in operation 607 of FIG. 6. The space between the frame 120 and the first support member 110F may be filled with the second-first support member 120G. The second-first support member 120G may be formed by insert injection molding (e.g., first insert injection molding). For example, the second-first support member 120G may be formed by inserting synthetic resin (or resin) into a mold in a state in which the frame 120 and the first support member 110F are formed. In one embodiment, the second-first support member 120G may be formed of a synthetic resin obtained by adding glass fibers to polybutylene terephthalate (PBT) resin. Alternatively, in one embodiment, the second-first support member 120G may be formed of a thermoplastic resin. For example, the second-first support member 120G may be formed of at least one from among polycarbonate (PC), polyphenylene sulfide (PPS), polyamide (PA), polyphthalamide (PPA), polyethylene terephthalate (PET), polyether ether ketone (PEEK), polyaryl ether ketone (PAEK), polyphenyl sulfone (PPSU), and a combination of two or more thereof. In this case, inorganic materials (e.g., glass fiber, carbon fiber, or talc) may be added to the second-first support member 120G to secure impact resistance. Regarding the formation position of the second-first support member 120G, a detailed description will be given below with reference to FIGS. 8 and 9.

In one embodiment, a film made of an organic material may be formed on the frame 120 and the first support member 110F. As one example, an organic film is formed on the frame 120 and the first support member 110F, so that the second-first support member 120G may be easily joined to the frame 120 and the first support member 110F through the organic film. For example, the organic film may be formed before injection-molding of the second-first support member 120G. The “joining” of the frame 120 and the first support member 110F and the second-first support member 120G may refer to physical coupling. For example, the frame 120 and the first support member 110F may be electrically connected to each other through the first welding portion 142b and the second welding portion 142a, and the frame 120 and the first support member 110F may be physically coupled by the formation of the second-first support member 120G.

FIG. 7G is a view illustrating a form of a frame (e.g., the frame 120 in FIG. 4), the first support member 110F, and the second-first support member 120G that have undergone a cutting process after the formation of the second-first support member 120G.

Referring to FIGS. 1A to 1C, FIGS. 4 to 7F, and FIG. 7G, in one embodiment, a cutting process of the second-first support member 120G may be performed in operation 609 of FIG. 6. As one example, at least a portion of a region, excluding a portion formed between the frame 120 and the first support member 110F, of the second-first support member 120G (e.g., a portion formed by protruding outside the frame 120) may be cut. For example, portions, excluding a portion that physically connects (or couples) the frame 120 and the first support member 110F, of the second-first support member 120G may be removed through cutting process (e.g., computer numerical control (CNC) process). In one embodiment, the cutting process may be performed a plurality of times (or repeatedly).

FIG. 7H is a view illustrating a form in which the second-second support member 121G is injection-molded.

Referring to FIGS. 1A to 1C, FIGS. 4 to 7G, and FIG. 7H, in one embodiment, the second-second support member 121G may be formed in operation 611 of FIG. 6. An internal space (or interspace) formed by the frame 120, the first support member 110F, and the second-first support member 120G may be filled with the second-second support member 121G. As one example, the gap 120d of the frame 120 may be filled with the second-second support member 121G. Therefore, the second-second support member 121G may form a portion of the side surface 110C of the electronic device 100 together with the corner portion 120a, the first side portion 120b, and the second side portion 120c. In one embodiment, the second-second support member 121G may be formed by insert injection molding (e.g., second insert injection molding). For example, the gap 120d of the frame 120 may be filled with at least a portion of an injection-molded product (e.g., the second-second support member 121G) formed through a second insert injection molding (e.g., a portion excluding a portion formed by protruding outside the frame 120 of the second-second support member 121G). For example, the second-second support member 121G may be formed by inserting resin (e.g., synthetic resin) into a mold in a state in which the frame 120, the first support member 110F, and the second-first support member 120G are formed. In one embodiment, the second-second support member 121G may be formed of a synthetic resin obtained by adding glass fibers to polybutylene terephthalate (PBT) resin. Alternatively, in one embodiment, the second-second support member 121G may be formed of a thermoplastic resin. For example, the second-second support member 121G may be formed of any one from among polycarbonate (PC), polyphenylene sulfide (PPS), polyamide (PA), polyphthalamide (PPA), polyethylene terephthalate (PET), polyether ether ketone (PEEK), polyaryl ether ketone (PAEK), and polyphenyl sulfone (PPSU). In this case, inorganic materials (e.g., glass fiber, carbon fiber, or talc) may be added to the second-second support member 121G to secure impact resistance. Regarding the formation position of the second-second support member 121G, a detailed description will be given below with reference to FIGS. 8 and 9.

In one embodiment, a film made of an organic material may be formed on the frame 120, the first support member 110F, and the second-first support member 120G. As one example, an organic film is formed on the frame 120, the first support member 110F, and the second-first support member 120G, so that the second-second support member 121G may be easily joined to the frame 120, the first support member 110F, and the second-first support member 120G through the organic film. For example, the organic film may be formed before injection molding of the second-second support member 121G. The “joining” of the frame 120, the first support member 110F, and the second-first support member 120G and the second-second support member 121G may refer to physical coupling. For example, a coupling force between the frame 120, the first support member 110F, and the second-first support member 120G may be supplemented by the second-second support member 121G.

FIG. 7I is a view illustrating a form of a frame (e.g., the frame 120 in FIG. 4), the first support member 110F, a second-first support member (e.g., the second-first support member 120G in FIG. 7G), and the second-second support member 121G that have undergone a cutting process after the formation of the second-second support member 121G.

Referring to FIGS. 1A to 1C, FIGS. 4 to 7H, and FIG. 7I, in one embodiment, a cutting process of the second-second support member 121G may be performed in operation 613 of FIG. 6. As one example, at least a portion of a region, excluding a portion formed between the frame 120, the first support member 110F, and the second-first support member 120G, of the second-second support member 121G (e.g., a portion formed by protruding outside the frame 120) may be cut. For example, portions, excluding a portion that physically connects (or couples) the frame 120, the first support member 110F, and the second-first support member 120G, of the second-second support member 121G may be removed through a cutting process (e.g., computer numerical control (CNC) process). In one embodiment, the cutting process may be performed a plurality of times (or repeatedly).

In one embodiment, anodizing and polishing processes may be performed in operation 615 of FIG. 6. For example, in the anodizing process, an oxide film may be formed on the surface of the first support member 110F. Then, in the polishing process, the oxide film formed on the portion (e.g., the corner portion 120a or the first outer portion 121b of the first side portion 120b) formed of a first metal (e.g., titanium) of the frame 120 may be removed.

FIG. 7J is a view illustrating a form in which a cutting process and particle blasting are performed on a frame (e.g., the frame 120 in FIG. 4), the first support member 110F, a second-first support member (e.g., the second-first support member 120G in FIG. 7G), and the second-second support member 121G that have undergone anodizing and polishing.

Referring to FIGS. 1A to 1C, FIGS. 4 to 7I, and FIG. 7J, in one embodiment, a cutting process of the frame 120, the first support member 110F, the second-first support member 120G, and the second-second support member 121G may be performed in operation 617 of FIG. 6. In this case, the cutting process may be performed substantially identically or similarly to the cutting process of the previous operation (e.g., operation 609 or operation 613 of FIG. 6). In operation 619 of FIG. 6, particle blasting of the frame 120, the first support member 110F, the second-first support member 120G, and the second-second support member 121G may be performed. In one embodiment, particle blasting may be an operation for completing the forms of the frame 120, the first support member 110F, the second-first support member 120G, and the second-second support member 121G into their final forms. For example, the forms of the side surface 110C of the electronic device 100 and the internal space of the electronic device 100 may be completed through particle blasting. In one embodiment, particles used in the particle blasting may be sand, or steel balls (or shot).

In one embodiment, the particle blasting process may be followed by a physical vapor deposition (PVD) process or an anti-fingerprint (AF) process. For example, various colors may be implemented on the exterior of the frame 120 as the exterior (e.g., the first outer portion 121b and the corner portion 120a formed of the first metal (titanium)) of the frame 120 polished through particle blasting is PVD-treated or AF-treated.

FIG. 8 is a view illustrating a structure in which a side portion of a frame and a first support member and a second support member are coupled according to an embodiment.

FIG. 8 is a view illustrating a cross-section taken along a line A-A′ of FIG. 4. Referring to FIGS. 1A to 1C, FIGS. 4 to 7J, and FIG. 8, in one embodiment, the first inner portion 122b may include a first surface 130b and a second surface 131b. The first surface 130b and the second surface 131b may be formed perpendicular to each other. As one example, the first surface 130b may be a surface (e.g., a surface facing the +x-axis direction) of the first inner portion 122b that is joined to the second-first support member 120G, and the second surface 131b may be a surface (e.g., a surface facing the +z-axis direction) of the first inner portion 122b that is joined to the first support member 110F. In one example, when the frame 120, the first support member 110F, and the second support member 110G are viewed from the +z axis, at least a portion of the second surface 131b may overlap with the first support member 110F.

The first side portion 120b and the first support member 110F may be electrically connected by the first welding portion 142b. In one embodiment, the first welding portion 142b may be formed on the second surface 131b. For example, the first welding portion 142b may be formed by melting the second surface 131b and the first support member 110F, and may have a form in which at least a portion of the welding portion 142b protrudes above the second surface 131b (e.g., in the +z-axis direction). In one embodiment, at least a portion of the first welding portion 142b may be in a form that protrudes downward (e.g., in the −z-axis direction) below the second surface 131b. In one example, one end of the first welding portion 142b (e.g., an end protruding in the +z-axis direction from the second surface 131b) may be covered by the first support member 110F, and the other end (e.g., an end protruding in the −z-axis direction from the second surface 131b) may be covered by the second-second support member 121G (e.g., a second portion 130g of the second-second support member 121G).

The first side portion 120b and the first support member 110F may be coupled (e.g., physically coupled) by the second support member 110G. In one embodiment, the second support member 110G may include the second-first support member 120G and the second-second support member 121G. For example, the second-first support member 120G may be formed (e.g., injection-molded) between the first inner portion 122b and the first support member 110F, and may be integrally joined together with the frame 120 and the first support member 110F. In one example, the final form of the second-first support member 120G (e.g., the form after all operations 601 to 619 in FIG. 6 are finished) may be a form formed parallel to the first inner portion 122b and the first support member 110F in one direction (e.g., in the x-axis direction). In this case, one surface (e.g., a surface facing the −x axis) of the second-first support member 120G may be joined to the first inner portion 122b, and the other surface (e.g., a surface facing the +x axis) may be joined to the first support member 110F. In one embodiment, the second-first support member 120G may be covered by the second-second support member 121G. For example, an upper portion (e.g., an upper portion in the z-axis direction) of the second-first support member 120G may be covered by the second-second support member 121G (e.g., a first portion 131g of the second-second support member 121G).

In one embodiment, the second-second support member 121G may be formed (e.g., injection-molded) between at least a portion of the first outer portion 121b and the first support member 110F. For example, the second-second support member 121G may be integrally coupled together with the frame 120, the first support member 110F, and the second-first support member 120G. In one example, the final form of the second-second support member 121G (e.g., the form after all of operations 601 to 619 in FIG. 6 are finished) may include a first portion 131g covering at least a portion of the first inner portion 122b, the second-first support member 120G, and the first support member 110F, and a second portion 130g supporting at least a portion of the first inner portion 122b, the second-first support member 120G, and the first support member 110F. With the formation of the second-second support member 121G, the coupling between the first side portion 120b and the first support member 110F may be maintained more firmly.

FIG. 9 is a view illustrating a structure in which a corner portion of a frame and a first support member and a second support member are coupled according to an embodiment.

FIG. 9 is a view illustrating a cross-section of FIG. 4 cut along a line B-B′. Referring to FIGS. 1A to 1C, FIGS. 4 to 8, and FIG. 9, in one embodiment, the corner portion 120a may include a third surface 130a and a fourth surface 131a. The third surface 130a and the fourth surface 131a may be formed perpendicular to each other. As one example, the third surface 130a may be a surface (e.g., a surface facing the +x-axis direction) of the corner portion 120a that is joined to the second-first support member 120G, and the fourth surface 131a may be a surface (e.g., a surface facing the +z-axis direction) of the corner portion 120a that is joined to the first support member 110F. In one example, when the frame 120, the first support member 110F, and the second support member 110G are viewed from the +z axis, at least a portion of the fourth surface 131a may overlap with the first support member 110F.

The corner portion 120a and the first support member 110F may be electrically connected by the second welding portion 142a. In one embodiment, the second welding portion 142a may be formed on the fourth surface 131a. For example, the second welding portion 142a may be formed by melting the fourth surface 131a and the first support member 110F, and may have a form in which at least a portion of the second welding portion 142a protrudes above the fourth surface 131a (e.g., in the +z-axis direction). In one embodiment, at least a portion of the second welding portion 142a may be in a form that protrudes downward (e.g., in the −z-axis direction) below the fourth surface 131a. In one example, one end of the second welding portion 142a (e.g., an end protruding in the +z-axis direction from the fourth surface 131a) may be covered by the first support member 110F, and the other end (e.g., an end protruding in the −z-axis direction from the fourth surface 131a) may be covered by the second-second support member 121G (e.g., the second portion 130g).

The corner portion 120a and the first support member 110F may be coupled (e.g., physically coupled) by the second support member 110G. In one embodiment, the second support member 110G may include the second-first support member 120G and the second-second support member 121G. For example, the second-first support member 120G may be formed (e.g., injection-molded) between the corner portion 120a and the first support member 110F, and may be integrally coupled together with the frame 120 and the first support member 110F. In one example, the final form of the second-first support member 120G (e.g., the form after all operations 601 to 619 of FIG. 6 are finished) may be a form formed between the corner portion 120a and the first support member 110F. For example, one surface (e.g., a surface facing outwards towards the outside of the electronic device 100) of the second-first support member 120G may be joined to the corner portion 120a, and the other side (e.g., a surface facing the inside of the electronic device 100) may be joined to the first support member 110F. In one embodiment, the second-first support member 120G may be covered by the second-second support member 121G. For example, an upper portion (e.g., an upper portion in the z-axis direction) of the second-first support member 120G may be covered by the second-second support member 121G (e.g., 131g).

The second-second support member 121G may be formed (e.g., injection-molded) between at least a portion of the corner portion 120a and the first support member 110F, and may be integrally coupled together with the frame 120, the first support member 110F, and the second-first support member 120G. In one example, the final form of the second-second support member 121G (e.g., the form after all of operations 601 to 619 of FIG. 6 are finished) may include the first portion 131g covering at least a portion of the corner portion 120a, the second-first support member 120G, and at least a portion of the first support member 110F, and the second portion 130g supporting at least a portion of the corner portion 120a and at least a portion of the first support member 110F. With the formation of the second-second support member 121G, the coupling between the corner portion 120a and the first support member 110F may be maintained more firmly.

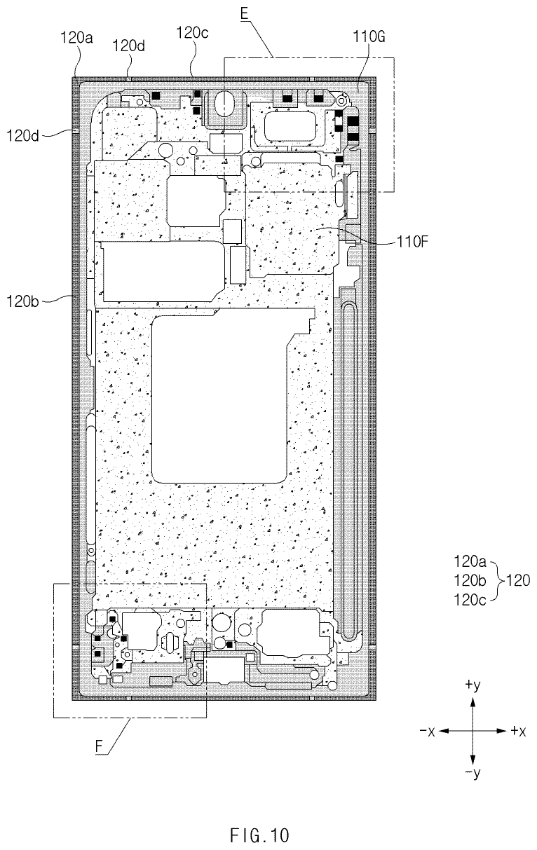

FIG. 10 is a view illustrating a form of a frame before a printed circuit board is mounted thereon according to an embodiment.

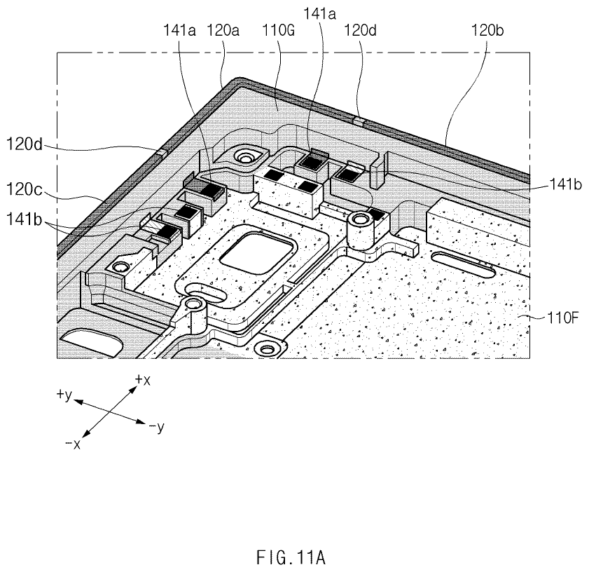

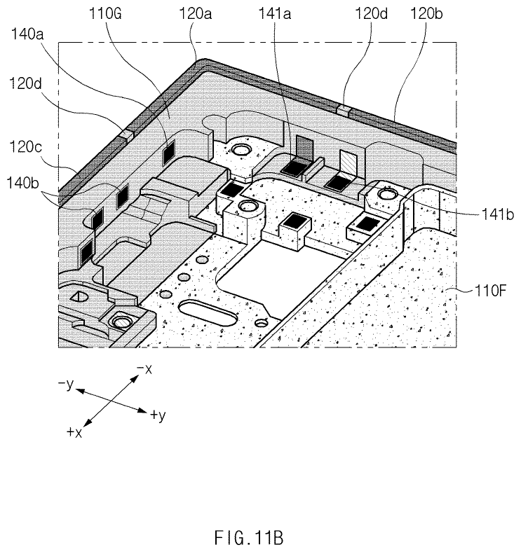

FIGS. 11A and 11B are views illustrating a contact portion of a frame according to an embodiment.

FIG. 10 is a view illustrating a state in which the frame 120 is coupled to the first support member 110F and the second support member 110G. FIG. 11A is an enlarged view of a region E in FIG. 10, and FIG. 11B is an enlarged view of a region F in FIG. 10. The region E in FIG. 10 may correspond to a region where a main printed circuit board (e.g., a main printed circuit board 111H in FIG. 12) (e.g., the first printed circuit board) is disposed, and the region F in FIG. 10 may correspond to a region where a sub-printed circuit board (e.g., a sub-printed circuit board 112H in FIG. 12) (e.g., the second printed circuit board) is disposed.

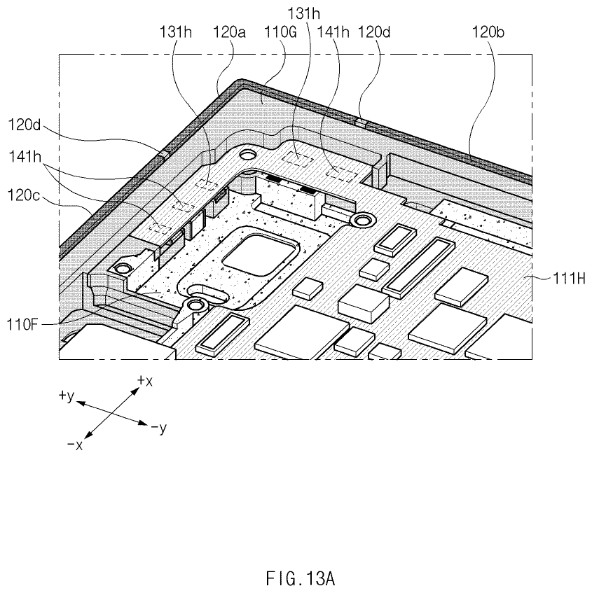

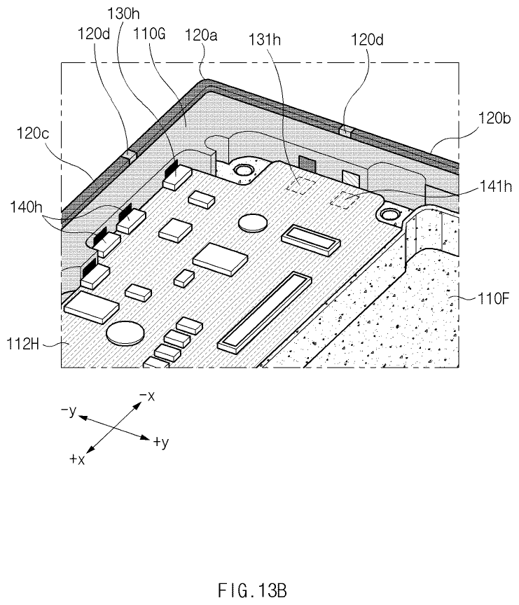

Referring to FIGS. 1A to 1C, FIGS. 4 to 9, FIG. 10, FIG. 11A, and FIG. 11B, in one embodiment, the second side portion 120c may include a first contact portion 140b and a second contact portion 141b. As one example, at least one from among the first contact portion 140b and the second contact portion 141b may be formed on a surface of the second inner portion (e.g., the second inner portion 122c in FIG. 7A) facing the inside of the electronic device 100. For example, the first contact portion 140b may be configured to attach (e.g., electrically connect) a component for electrical connection to the second inner portion 122c. For example, the component may include a conductive pad (e.g., a metal sheet). In one embodiment, the first contact portion 140b and the second contact portion 141b may be formed on surfaces of the second side portion 120c perpendicular to each other. Alternatively, as one example, at least one from among the first contact portion 140b and the second contact portion 141b may be formed to protrude from the second side portion 120c. For example, the second contact portion 141b formed to protrude from the second side portion 120c in a direction toward the interior of the electronic device 100 may be formed on the second side portion 120c. For example, a connection point (e.g., a ground point and/or a power supply point) (e.g., a metal sheet) for electrical connection may be disposed at one end of a flange (e.g., the second contact portion 141b) formed by protruding from a point of the second side portion 120c. In one embodiment, the first contact portion 140b and the second contact portion 141b may protrude from the second side portion 120c in a direction perpendicular to each other. In one embodiment, the first contact portion 140b and the second contact portion 141b may be in contact with a printed circuit board (e.g., the first printed circuit board 110H in FIG. 12). In this regard, a detailed description will be given below with reference to FIGS. 12 to 13B. In one embodiment, the structure of the first side portion 120b may be formed substantially identically to a structure of the second side portion 120c. For example, the first side portion 120b may include a first contact portion (e.g., first contact portion 140b) and a second contact portion (e.g., second contact portion 141b). The first contact portion (e.g., first contact portion 140b) may be, for example, disposed on a surface parallel to the first surface 130b of the first inner portion 122b, or may protrude from a surface parallel to the first surface 130b. The second contact portion (e.g., 141b) may be, for example, disposed on a surface parallel to the second surface 131b of the first inner portion 122b, or may protrude from a surface parallel to the second surface 131b.

In one embodiment, the corner portion 120a may include a third contact portion 140a and a fourth contact portion 141a. As one example, at least one from among the third contact portion 140a and the fourth contact portion 141a may be formed on a surface of the corner portion 120a facing the inside of the electronic device 100. For example, the third contact portion 140a may be configured to attach (e.g., electrically connect) a component for electrical connection to the corner portion 120a. For example, the component may include a conductive pad (e.g., a metal sheet). In one embodiment, the third contact portion 140a and the fourth contact portion 141a may be formed on surfaces of the corner portion 120a perpendicular to each other. Alternatively, as one example, at least one from among the third contact portion 140a and the fourth contact portion 141a may be formed to protrude from the corner portion 120a. For example, the fourth contact portion 141a formed to protrude in a direction from the corner portion 120a toward the inside of the electronic device 100 may be formed on the corner portion 120a. For example, a connection point (e.g., a ground point and/or a power supply point) (e.g., a metal sheet) for electrical connection may be disposed at one end of a flange (e.g., the fourth contact portion 141a) formed by protruding from a point of the corner portion 120a. In one embodiment, the third contact portion 140a and the fourth contact portion 141a may protrude in a direction perpendicular to each other from the corner portion 120a. In one embodiment, the third contact portion 140a and the fourth contact portion 141a may be in contact with a printed circuit board (e.g., the first printed circuit board 110H in FIG. 12). In this regard, a detailed description will be given below with reference to FIGS. 12 to 13B.

In one embodiment, the forms of the first contact portion 140b and the second contact portion 141b formed on the second side portion 120c, and the forms of the third contact portion 140a and the fourth contact portion 141a formed on the corner portion 120a, may appear substantially the same in the regions E and F in FIG. 10. However, the contact portions (e.g., the first contact portion 140b, the second contact portion 141b, the third contact portion 140a, and the fourth contact portion 141a) are not limited to the above-described contents and may be formed in different forms. In addition, in one embodiment, the forms of the contact portions (e.g., the first contact portion 140b, the second contact portion 141b, the third contact portion 140a, and the fourth contact portion 141a) in the regions E and F in FIG. 10 may be differently formed. In one embodiment, the first contact portion 140b and the second contact portion 141b may be formed of the second metal (e.g., aluminum), and the third contact portion 140a and the fourth contact portion 141a may be formed of the first metal (e.g., titanium).

FIG. 12 is a view illustrating a form of a frame after a printed circuit board is mounted thereon according to an embodiment.

FIGS. 13A and 13B are views illustrating a form in which the frame and the printed circuit board are electrically connected according to an embodiment.

FIG. 12 is a view illustrating a form in which a first printed circuit board 110H is disposed in a state in which the frame 120, the first support member 110F, and the second support member 110G in FIG. 10 are coupled. FIG. 13A is an enlarged view of a region G in FIG. 12, and FIG. 13B is an enlarged view of a region H in FIG. 12. The region G in FIG. 12 may correspond to the region in which a main printed circuit board 111H is disposed in the region E in FIG. 10, and the region H in FIG. 12 may correspond to a region in which a sub-printed circuit board 112H is disposed in the region F in FIG. 10.

Referring to FIGS. 1A to 1C, FIGS. 4 to 11B, FIG. 12, FIG. 13A, and FIG. 13B, in one embodiment, the first printed circuit board 110H (or circuit board) may include the main printed circuit board 111H and the sub-printed circuit board 112H disposed on a first support member 110F. In one embodiment, the first printed circuit board 110H may include a plurality of communication circuits. As one example, the main printed circuit board 111H may include a first communication circuit supporting a first frequency band, and a second communication circuit supporting a second frequency band. In addition, in one embodiment, the sub-printed circuit board 112H may include a third communication circuit supporting a third frequency band. The first frequency band, the second frequency band, and the third frequency band may not overlap each other.

In one embodiment, the main printed circuit board 111H may include two or more printed circuit boards. For example, the main printed circuit board 111H may have a form in which two or more separate printed circuit boards are coupled. For example, the main printed circuit board 111H may include a third printed circuit board and a fourth printed circuit board that are formed separately from each other. For example, the third printed circuit board may include a region that comes into contact with a second side portion 120c and a corner portion 120a of the main printed circuit board 111H (e.g., a region where a third terminal 131h and a fourth terminal 141h of the main printed circuit board 111H in FIG. 13A are disposed). For example, the fourth printed circuit board may include a region where various components (e.g., a processor, memory, a wireless communication module, or the like) of the main printed circuit board 111H are disposed. The third printed circuit board and the fourth printed circuit board may be physically connected and/or electrically connected to each other.

In one embodiment, the first printed circuit board 110H may be electrically connected to the frame 120 through at least one ground point and/or feed point. At least a portion of the frame 120 (e.g., the corner portion 120a, the first side portion 120b, and the second side portion 120c) may be used as an antenna radiator. As one example, the corner portion 120a may be connected to the first communication circuit of the main printed circuit board 111H to be used as an antenna of the first communication circuit, and the first side portion 120b may be connected to the second communication circuit of the main printed circuit board 111H to be used as an antenna of the second communication circuit. In this case, in one embodiment, the corner portion 120a may be operated for a low frequency band of a cellular band, and the first side portion 120b may be operated for a Wi-Fi band. Hereinafter, an electrical connection method between the first printed circuit board 110H and the frame 120 is described.

The sub-printed circuit board 112H may include contact terminals that come into contact with the frame 120. For example, the sub-printed circuit board 112H may include a first terminal 130h and a second terminal 140h connected to the ground of the sub-printed circuit board 112H, and a third terminal 131h and a fourth terminal 141h connected to the third communication circuit of the sub-printed circuit board 112H. In one embodiment, the first terminal 130h and the second terminal 140h may be in contact with a ground point of the frame 120 (e.g., the first contact portion 140b or the third contact portion 140a in FIG. 11B). As one example, the first terminal 130h may be in contact with the third contact portion 140a of the corner portion 120a, and the second terminal 140h may be in contact with the first contact portion 140b of the second side portion 120c. In one embodiment, the third terminal 131h and the fourth terminal 141h may be in contact with an antenna feed (or a feeding portion) of the frame 120 (e.g., the second contact portion 141b or the fourth contact portion 141a in FIG. 11A). As one example, the third terminal 131h may be in contact with the fourth contact portion 141a of the corner portion 120a, and the fourth terminal 141h may be in contact with the second contact portion 141b of the first side portion 120b. In one embodiment, the terminals (e.g., the first terminal 130h, the second terminal 140h, the third terminal 131h, and the fourth terminal 141h) may be in contact (e.g., electrically connected) with the contact portions (e.g., the first contact portion 140b, the second contact portion 141b, the third contact portion 140a, and the fourth contact portion 141a) through any one of a connector (e.g., a coaxial connector, a C-Clip connector), a pogo pin, or any other connecting member. In one embodiment, a conductive material (e.g., a metal sheet) may be attached to at least one from among the contact portions (e.g., the first contact portion 140b, the second contact portion 141b, the third contact portion 140a, and the fourth contact portion 141a) so as to be stably in contact with (e.g., electrically connected to) the terminals (e.g., the first terminal 130h, the second terminal 140h, the third terminal 131h, and the fourth terminal 141h).

The main printed circuit board 111H may include contact terminals that come into contact with the frame 120. For example, the main printed circuit board 111H may include a first terminal (e.g., the first terminal 130h in FIG. 13B) and a second terminal (e.g., the second terminal 140h in FIG. 13B) connected to the ground of the main printed circuit board 111H, and the third terminal 131h and the fourth terminal 141h connected to the first communication circuit of the main printed circuit board 111H. Regarding the main printed circuit board 111H, the description provided regarding the sub-printed circuit board 112H may be substantially identically referenced. However, in one embodiment, the contact forms of the main printed circuit board 111H and the sub-printed circuit board 112H with the frame 120 may be differently formed.

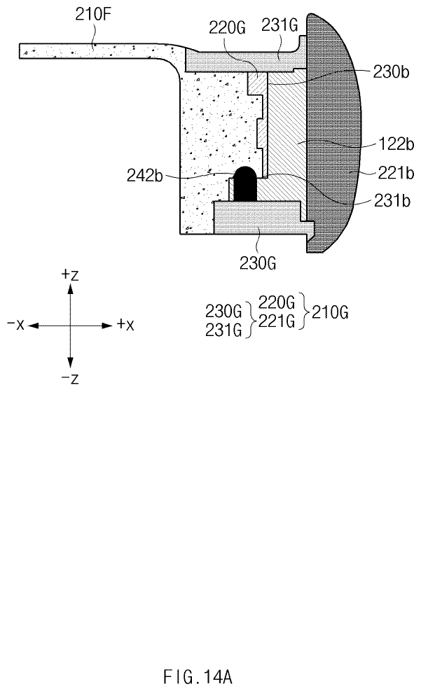

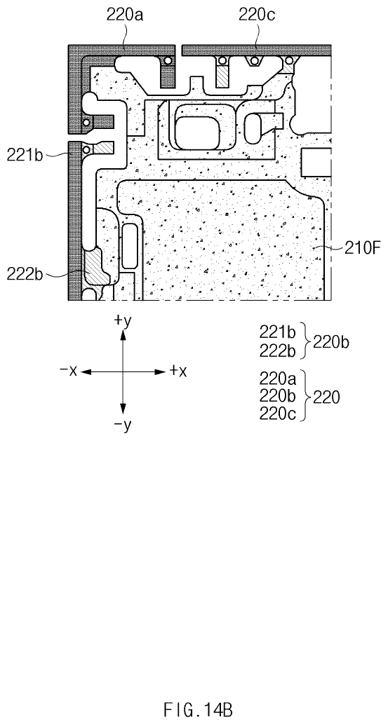

FIGS. 14A and 14B are views illustrating a form in which a frame of an electronic device according to an embodiment is formed using stainless steel.

FIG. 14A is a view illustrating a structure in which a first side portion 220b, a first support member 210F, and a second support member 210G of a frame 220 are coupled according to an embodiment. FIG. 14B is a view illustrating a form in which the frame 220, the first support member 210F, and the second support member 210G are coupled, as viewed from the +z-axis direction according to an embodiment.

Referring to FIGS. 1A to 1C, FIGS. 4 to 13B, and FIGS. 14A and 14B, in one embodiment, the frame 220 may include a corner portion 220a; a first side portion 220b including a first outer portion 221b and a first inner portion 222b; and a second side portion 220c. The frame 220 may include a second metal (e.g., aluminum) and a third metal (e.g., stainless steel). As one example, the first side portion 220b and the second side portion 220c may be formed of a clad metal in which the second metal and the third metal are coupled. For example, the first outer portion 221b and the corner portion 220a may be formed of the third metal, and the first inner portion 222b may be formed of the second metal. In this case, the third metal (e.g., stainless steel) may form the exterior of the electronic device (e.g., electronic device 100 in FIG. 1A). To the frame 220, the description provided for frame 120 in FIG. 4 may be applied. To the corner portion 220a, the description provided for the corner portion 120a in FIG. 4 may be applied. To the first side portion 220b, the description provided for the first side portion 120b in FIG. 4 may be applied. To the first outer portion 221b, the description provided for the first outer portion 121b in FIG. 5 may be applied. To the first inner portion 222b, the description provided for the first inner portion 122b in FIG. 5 may be applied. To a first surface 230b, the description provided for the first surface 130b in FIG. 8 may be applied. To a second surface 231b, the description provided for the second surface 131b in FIG. 8 may be applied. To a first welding portion 242b, the description provided for the first welding portion 142b in FIG. 8 may be applied. To the second side portion 220c, the description provided for the second side portion 120c in FIG. 4 may be applied. To the first support member 210F, the description provided for the first support member 110F in FIG. 4 may be applied. To the second support member 210G, the description provided for the second support member 110G in FIG. 4 may be applied. To a second-first support member 220G, the description provided for the second-first support member 120G in FIG. 8 may be applied. To a second-second support member 221G, the description provided for the second-second support member 121G in FIG. 8 may be applied. To a first portion 231g of the second-second support member 221G, the description provided for the first portion 131g of the second-second support member 121G in FIG. 8 may be applied. To a second portion 230g of the second-second support member 221G, the description provided for the second portion 130g of the second-second support member 121G in FIG. 8 may be applied.

FIG. 15 is a view schematically illustrating a portion of a frame of an electronic device according to an embodiment.

FIG. 15 is a view illustrating a portion of a first housing 310 and a portion of a hinge housing 350 with reference to FIGS. 2A to 2C.

Referring to FIGS. 2A to 2C and FIG. 15, in one embodiment, the first housing 310 may include a first side member 313 forming a portion of a frame of an electronic device 300, and a support portion 328 disposed on an inner side of the frame. The first side member 313 may include a hinge side frame portion 313a, an edge frame portion 313b, and a corner frame portion 313c. The hinge side frame portion 313a may be defined as a portion (e.g., a left portion in FIG. 15) that is coupled to the hinge housing 350 of the first side member 313. The edge frame portion 313b may be defined as a portion (e.g., a right portion in FIG. 15) formed in the opposite direction to (e.g., to face away from) the hinge side frame portion 313a of the first side member 313. The corner frame portion 313c may be defined as a portion formed on both sides of the edge frame portion 313b (e.g., in the +y-axis direction and the −y-axis direction). In one example, the hinge side frame portion 313a may include an extension portion 3132 extending in the y-axis direction, and a protruding portion 3133 extending from the extension portion 3132 in the +x-axis direction. Accordingly, the hinge side frame portion 313a may form at least a portion of a corner (e.g., a point where two edges meet) of the first housing 310. At least one gap 313d may be formed between the hinge side frame portion 313a and the corner frame portion 313c. In addition, the gap 313d may also be formed between the corner frame portion 313c and the edge frame portion 313b. Due to the gap 313d, the hinge side frame portion 313a, the edge frame portion 313b, and the corner frame portion 313c may each be used as an antenna radiator as a segment. The support portion 328 may be joined (e.g., electrically connected) to the hinge side frame portion 313a, the edge frame portion 313b, and the corner frame portion 313c by welding and then completely coupled through insert injection molding.

In one embodiment, the hinge side frame portion 313a and the corner frame portion 313c may be formed from a first metal (e.g., titanium). In addition, in one embodiment, the edge frame portion 313b may include an outer frame portion 333b formed from the first metal (e.g., titanium), and an inner frame portion 343b formed from a second metal (e.g., aluminum). In one embodiment, the support portion 328 may be formed from the second metal (e.g., aluminum). In various embodiments, the support portion 328 may be formed from a fourth metal (e.g., magnesium). In this case, the support portion 328 may be formed to be light compared to when formed from the second metal.

In one embodiment, a first antenna feed may be formed in the corner frame portion 313c. In addition, a second antenna feed may be formed in the edge frame portion 313b. For example, the first antenna feed may be formed as a contact point that electrically connects a printed circuit board (e.g., the first printed circuit board 110H in FIG. 12) disposed inside the electronic device 300 (e.g., disposed on the support portion 328) and the corner frame portion 313c.

To the first side member 313 in FIG. 15, the description provided regarding the frame 120 in FIGS. 1A to 1C and FIGS. 4 to 14B may be applied. To the hinge side frame portion 313a in FIG. 15, the description provided regarding the corner portion 120a in FIGS. 4 to 14B may be applied. To the edge frame portion 313b in FIG. 15, the description provided regarding the first side portion 120b in FIGS. 4 to 14B may be applied. To the corner frame portion 313c in FIG. 15, the description provided regarding the corner portion 120a in FIGS. 4 to 14B may be applied. To the inner frame portion 343b in FIG. 15, the description provided regarding to the first inner portion 122b in FIGS. 5 to 14B may be applied. To the outer frame portion 333b in FIG. 15, the description provided regarding the first outer portion 121b in FIGS. 5 to 14B may be applied. To the support portion 328 in FIG. 15, the description provided regarding the first support member 110F and the second support member 110G in FIGS. 4 to 14B may be applied.

FIG. 16 is a view schematically illustrating a portion of a frame of an electronic device according to an embodiment.

FIG. 16 is a view illustrating a portion of the first housing 410 and a portion of a hinge housing 450 with reference to FIGS. 3A to 3C.

Referring to FIGS. 3A to 3C and FIG. 16, in one embodiment, the first housing 410 may include a first side member 413 forming a portion of a frame of the electronic device 400, and a support portion 428 disposed on an inner side of the frame. The first side member 413 may include a hinge side frame portion 413a, an edge frame portion 413b, and a corner frame portion 413c. The hinge side frame portion 413a may be defined as a portion (e.g., the lower portion in FIG. 16) that is coupled to the hinge housing 450 of the first side member 413. The edge frame portion 413b may be defined as a portion (e.g., the upper portion in FIG. 16) formed in the opposite direction to (e.g., to face away from) the hinge side frame portion 413a of the first side member 413. The corner frame portion 413c may be defined as a portion formed on both sides of the edge frame portion 413b (e.g., in the +x-axis direction and the −x-axis direction). At least one gap 413d may be formed between the hinge side frame portion 413a and the corner frame portion 413c. In addition, the gap 413d may also be formed between the corner frame portion 413c and the edge frame portion 413b. Due to the gap 413d, the hinge side frame portion 413a, the edge frame portion 413b, and the corner frame portion 413c may each be used as an antenna radiator as a segment. The support portion 428 may be joined (e.g., electrically connected) to the hinge side frame portion 413a, the edge frame portion 413b, and the corner frame portion 413c by welding and then completely coupled through insert injection molding.

In one embodiment, the hinge side frame portion 413a and the corner frame portion 413c may be formed from a first metal (e.g., titanium). In addition, in one embodiment, the edge frame portion 413b may include an outer frame portion 433b formed from the first metal (e.g., titanium), and an inner frame portion 443b formed from a second metal (e.g., aluminum). In one embodiment, the support portion 428 may be formed from the second metal (e.g., aluminum). In various embodiments, the support portion 428 may be formed from a fourth metal (e.g., magnesium). In this case, the support portion 428 may be formed to be light compared to when formed from the second metal.

In one embodiment, a first antenna feed may be formed in the corner frame portion 413c. In addition, a second antenna feed may be formed in the edge frame portion 413b. For example, the first antenna feed may be formed as a contact point that electrically connects a printed circuit board (e.g., the first printed circuit board 110H in FIG. 12) disposed inside the electronic device 400 (e.g., disposed on the support portion 428) and the corner frame portion 413c.

To the first side member 413 in FIG. 16, the description provided regarding the frame 120 in FIGS. 1A to 1C and FIGS. 4 to 14B may be applied. To the hinge side frame portion 413a in FIG. 16, the description provided regarding the corner portion 120a in FIGS. 4 to 14B may be applied. To the edge frame portion 413b in FIG. 16, the description provided regarding the first side portion 120b in FIGS. 4 to 14B may be applied. To the corner frame portion 413c in FIG. 16, the description provided regarding the corner portion 120a in FIGS. 4 to 14B may be applied. To the inner frame portion 443b in FIG. 16, the description provided regarding to the first inner portion 122b in FIGS. 5 to 14B may be applied. To the outer frame portion 433b in FIG. 16, the description provided regarding the first outer portion 121b in FIGS. 5 to 14B may be applied. To the support portion 428 in FIG. 16, the description provided regarding the first support member 110F and the second support member 110G in FIGS. 4 to 14B may be applied.

In various embodiments, a frame (e.g., the frame 120 in FIG. 4) of an electronic device (e.g., the electronic device 100 in FIG. 1A) may include a support member (e.g., the first support member 110F in FIG. 4 and the second support member 110G in FIG. 4). For example, the frame may be formed as one body in which a corner portion (e.g., the corner portion 120a in FIG. 4), a first side portion (e.g., the first side portion 120b in FIG. 4), a second side portion (e.g., the second side portion 120c in FIG. 4), a third side portion (e.g., the third side portion 120b′ in FIG. 4), a fourth side portion (e.g., the fourth side portion 120c′ in FIG. 4), the first support member 110F, and the second support member 110G are coupled.

In various embodiments, a frame (e.g., the first side member 313 in FIG. 2A) of an electronic device (e.g., the electronic device 300 in FIG. 2A) may include a support member (e.g., the support portion 328 in FIG. 15). For example, the frame (or the first side member 313) may be formed as one body in which a hinge side frame portion (e.g., the hinge side frame portion 313a in FIG. 15), an edge frame portion (e.g., the edge frame portion 313b in FIG. 15), a corner frame portion (e.g., the corner frame portion 313c in FIG. 15), and the support portion 328 are coupled.

In various embodiments, a frame (e.g., the first side member 413 in FIG. 3A) of an electronic device (e.g., the electronic device 400 in FIG. 3A) may include a support member (e.g., the support portion 428 in FIG. 16). For example, the frame (or the first side member 413) may be formed as one body in which a hinge side frame portion (e.g., the hinge side frame portion 413a in FIG. 16), an edge frame portion (e.g., the edge frame portion 413b in FIG. 16), a corner frame portion (e.g., the corner frame portion 413c in FIG. 16), and the support portion 428 are coupled.

In various embodiments, in the first side portion (e.g., the first side portion 120b in FIG. 4), a first outer portion (e.g., the first outer portion 121b in FIG. 4) and a first inner portion (e.g., the first inner portion 122b in FIG. 4) may be formed to have the same thickness in a second direction (e.g., the +x-axis direction). Alternatively, in various embodiments, the thicknesses of the first outer portion 121b and the first inner portion 122b in the second direction may be differently formed. In addition, the thickness of each of the first outer portion 121b and the first inner portion 122b in the second direction may be differently formed within the first side portion 120b. For example, the thickness of the first inner portion 122b positioned at the upper portion (e.g., a +y-axis portion) of the first side portion 120b in the second direction may be formed to be thicker than the thickness of the first inner portion 122b positioned at the lower portion (e.g., a −y-axis portion) in the second direction. In addition, the thickness of the corner portion (e.g., the corner portion 120a in FIG. 4) and the thickness of the first outer portion 121b may be formed to be the same as or different from each other. For example, the thickness of the corner portion 120a in the second direction may be formed to be thicker than the thickness of the first side portion 120b in the second direction.

In various embodiments, the outer frame portion (e.g., the outer frame portion 333b in FIG. 15) and the inner frame portion (e.g., the inner frame portion 343b in FIG. 15) of the corner frame portion (e.g., the edge frame portion 313b in FIG. 15) may be formed with the same thickness in the second direction (e.g., the +x-axis direction). Alternatively, in various embodiments, the thicknesses of the outer frame portion 333b and the inner frame portion 343b in the second direction may be differently formed. In addition, the thickness of each of the outer frame portion 333b and the inner frame portion 343b in the second direction may be formed differently within the edge frame portion 313b. For example, the thickness of the inner frame portion 343b positioned at the upper portion (e.g., at a +y-axis portion) of the edge frame portion 313b in the second direction may be formed to be thicker than the thickness of the inner frame portion 343b positioned at a lower portion (e.g., at a −y-axis portion) in the second direction. In addition, the thickness of the corner frame portion (e.g., the corner frame portion 313c in FIG. 15) and the thickness of the outer frame portion 333b may be formed to be the same or different. For example, the thickness of the corner frame portion 313c in the second direction may be formed to be thicker than the thickness of the edge frame portion 313b in the second direction. The above-described content may be equally applied to the first side member 413 in FIG. 16.

In various embodiments, the curvature of the corner portion 120a and/or the corner frame portion (e.g., the corner frame portion 313c in FIG. 15 or the corner frame portion 413c in FIG. 16) may be formed to be 10R or less (e.g., the radius of curvature is 10 mm or less). For example, the radius of curvature of the corner portion 120a and/or the corner frame portion (e.g., the corner frame portion 313c in FIG. 15 or the corner frame portion 413c in FIG. 16) may be formed to have a radius within a range of 0.5 mm to 10 mm.

In various embodiments, referring to FIG. 4, at least one or two or more from among the coupled structures of the frame (e.g., the frame 120 or frame 220 in FIGS. 14A and 14B), the first support member 110F, and the second support member 110G may be applied to various electronic devices. As one example, the structure of the corner portion 120a formed of a single metal (e.g., the first metal) and the first side portion 120b including the clad metal may be applied to various electronic devices. Alternatively, as one example, the structure in which the corner portion 120a and the first side portion 120b are coupled to the first support member 110F by welding and/or the structure in which the corner portion 120a, the first side portion 120b, and the first support member 110F are coupled to the second support member 110G by insert injection molding may be applied to various electronic devices. The electronic device may include, for example, a multi-foldable electronic device, a rollable electronic device, a wearable electronic device (e.g., a smart watch, a smart ring, or a virtual reality (VR) electronic device, or the like), or a laptop.

In various embodiments, the coupled structure of at least one or two from among the first side member (e.g., the first side member 313 in FIG. 15 or the first side member 413 in FIG. 16) and the support portion (e.g., the support portion 328 in FIG. 15 or the support portion 428 in FIG. 16) may be applied to various electronic devices. As one example, a structure of the hinge side frame portion (e.g., the hinge side frame portion 313a in FIG. 15 or the hinge side frame portion 413a in FIG. 16) formed of a single metal (e.g., the first metal), the corner frame portion (e.g., the corner frame portion 313c in FIG. 15 or the corner frame portion 413c in FIG. 16), and the edge frame portion (e.g., the edge frame portion 313b in FIG. 15 or the edge frame portion 413b in FIG. 16) including a clad metal may be applied to various electronic devices. Alternatively, as one example, a structure in which the hinge side frame portion (e.g., the hinge side frame portion 313a in FIG. 15 or the hinge side frame portion 413a in FIG. 16), the corner frame portion (e.g., the corner frame portion 313c in FIG. 15 or the corner frame portion 413c in FIG. 16), the edge frame portion (e.g., the edge frame portion 313b in FIG. 15 or the edge frame portion 413b in FIG. 16), and the support portion (e.g., the support portion 328 in FIG. 15 or the support portion 428 in FIG. 16) are coupled by welding and insert injection molding may be applied to various electronic devices. The electronic device may include, for example, a multi-foldable electronic device, a rollable electronic device, a wearable electronic device (e.g., a smart watch, a smart ring, or a virtual reality (VR) electronic device, a laptop, or the like).

According to an embodiment of the present disclosure, an electronic device may include a frame defining at least a portion of a side surface of the electronic device and a support portion disposed on an inner side of the frame, the frame may include a corner portion defining a portion of the side surface and including a first metal, and a side portion defining another portion of the side surface and including a clad structure in which an outer portion including the first metal and an inner portion including a second metal are joined, and the support portion may be connected to the corner portion and the side portion by welding.

According to an embodiment of the present disclosure, the electronic device may further include a non-conductive member configured to couple the inner portion, the corner portion, and the support portion, and the non-conductive member may be disposed to fill a space between the corner portion and the side portion.

According to an embodiment of the present disclosure, a first connecting portion may be formed on the inner portion so that the inner portion and the support portion are electrically connected, and a second connecting portion may be formed on the corner portion so that the corner portion and the support portion are electrically connected.

According to an embodiment of the present disclosure, the inner portion may include a first surface coupled to the non-conductive member and a second surface that is adjacent to the first surface and on which the first connecting portion is formed, and the corner portion may include a third surface coupled to the non-conductive member and a fourth surface that is adjacent to the third surface and on which the second connecting portion is formed.

According to an embodiment of the present disclosure, a first contact portion extending from the first surface and a second contact portion extending from the second surface may be formed in the inner portion, a third contact portion extending from the third surface and a fourth contact portion extending from the fourth surface may be formed in the corner portion, the first contact portion and the second contact portion may include the second metal, and the third contact portion and the fourth contact portion may include the first metal.

According to an embodiment of the present disclosure, the electronic device may further include a printed circuit board disposed inside the electronic device, at least one from among the first contact portion, the second contact portion, the third contact portion, and the fourth contact portion may be configured to be connected to the printed circuit board to function as an antenna, and another one from among the first contact portion, the second contact portion, the third contact portion, and the fourth contact portion may be connected to a ground of the printed circuit board.

According to an embodiment of the present disclosure, the first metal may be a titanium alloy and the second metal may be an aluminum alloy.

According to an embodiment of the present disclosure, the first metal may be stainless steel and the second metal may be an aluminum alloy.

According to an embodiment of the present disclosure, an electronic device may include a display, a rear cover, and a frame structure at least partially disposed between the display and the rear cover, the frame structure may include a first side portion defining a portion of a first side surface of the electronic device and at least partially made of a clad structure formed from a first metal and a second metal, in the clad structure, the first metal being disposed toward an outside of the electronic device and the second metal being disposed toward an inside of the electronic device, a second side portion forming a portion of a second side surface of the electronic device and at least partially made of the clad structure, a corner portion defining another portion of the first side surface and another portion of the second side surface between the first side portion and the second side portion and formed from the first metal, the corner portion including a first antenna feed formed from the first metal, a support portion supporting the display, coupled to the first side portion and the corner portion, and formed from the second metal.

According to an embodiment of the present disclosure, the second side portion may include a second antenna feed formed from the second metal.

According to an embodiment of the present disclosure, the electronic device may further include a printed circuit board supported by the support portion, the corner portion may include a ground point formed from the first metal, and the ground point may be electrically connected to a ground surface of the printed circuit board.

According to an embodiment of the present disclosure, the first antenna feed and the ground point may protrude in different directions toward an interior of the electronic device.

According to an embodiment of the present disclosure, the printed circuit board may include a first communication circuit supporting a first frequency band and a second communication circuit supporting a second frequency band, the first antenna feed may be electrically connected to a first terminal formed on the printed circuit board and connected to the first communication circuit, and the second antenna feed may be electrically connected to a second terminal formed on the printed circuit board and connected to the second communication circuit.

According to an embodiment of the present disclosure, a first surface facing toward an interior of the electronic device and a second surface perpendicular to the first surface and overlapping the support portion when viewed from a front of the electronic device may be formed from the second metal of the first side portion, the first surface and the support portion may be coupled through a first insert injection molding, and the second surface and the support portion may be coupled through a first welding portion.

According to an embodiment of the present disclosure, a third surface facing toward an interior of the electronic device and a fourth surface perpendicular to the third surface and overlapping the support portion when viewed from the front may be formed from the first metal of the corner portion, the third surface and the support portion may be coupled through the first insert injection molding, and the fourth surface and the support portion may be coupled through a second welding portion.

According to an embodiment of the present disclosure, the first welding portion and the second welding portion may be covered by a second insert injection molding.

According to an embodiment of the present disclosure, at least a portion of the first insert injection molding is covered by the second insert injection molding.

According to an embodiment of the present disclosure, a radius of curvature of a region, where the other portion of the first side surface and the other portion of the second side surface meet, of the corner portion may be greater than 0.5 mm and less than 8 mm.

According to an embodiment of the present disclosure, a foldable electronic device including a hinge module, a first housing and a second housing coupled to be foldable about the hinge module, and a hinge cover coupled to the hinge module may include a frame having at least a portion included in the first housing, the second housing, and the hinge cover and a support portion disposed inside the frame, the frame may include a hinge side frame portion coupled to the hinge cover and having at least a portion defining a portion of a side surface of the foldable electronic device in a state in which the first housing and the second housing are folded, an edge frame portion defining another portion of the side surface opposite the hinge side frame portion, and a corner frame portion disposed on one side of the edge frame portion to form a corner portion of the side surface, the hinge side frame portion and the corner frame portion may be formed from a first metal, the edge frame portion may be made of a clad structure formed from the first metal and a second metal, and the support portion may be connected to the corner frame portion and the edge frame portion by welding.

According to an embodiment of the present disclosure, the corner frame portion may include a first antenna feed that protrudes toward an inside of the foldable electronic device and is formed from the first metal, and the edge frame portion may include a second antenna feed that protrudes toward the inside of the foldable electronic device and is formed from the second metal.

What is claimed is:

1. An electronic device, comprising:
a frame; and
a support portion on an inner side of the frame,
wherein the frame comprises:
a corner portion defining a first portion of a side surface of the electronic device, the corner portion comprising a first metal; and
a side portion defining a second portion of the side surface, the side portion comprising a clad structure comprising an outer portion and an inner portion that are joined together,
wherein the outer portion comprises the first metal, and the inner portion comprises a second metal, different from the first metal, and
wherein the support portion is connected to the corner portion and the side portion by welding.

2. The electronic device according to claim 1, further comprising a non-conductive member that connects the inner portion, the corner portion, and the support portion,
wherein the non-conductive member fills a space between the corner portion and the side portion.

3. The electronic device according to claim 2, wherein a first connecting portion is on the inner portion and electrically connects the inner portion and the support portion, and
wherein a second connecting portion is on the corner portion and electrically connects the corner portion and the support portion.

4. The electronic device according to claim 3, wherein the inner portion comprises a first surface connected to the non-conductive member, and a second surface that is adjacent to the first surface,
wherein the first connecting portion is on the second surface,
wherein the corner portion comprises a third surface connected to the non-conductive member, and a fourth surface that is adjacent to the third surface, and
wherein the second connecting portion is on the fourth surface.

5. The electronic device according to claim 4, wherein a first contact portion extends from the first surface, and a second contact portion extends from the second surface,
wherein a third contact portion extends from the third surface, and a fourth contact portion extends from the fourth surface,
wherein the first contact portion and the second contact portion comprise the second metal, and
wherein the third contact portion and the fourth contact portion comprise the first metal.

6. The electronic device according to claim 5, further comprising a printed circuit board,
wherein at least one from among the first contact portion, the second contact portion, the third contact portion, and the fourth contact portion is configured to be connected to the printed circuit board to function as an antenna, and
wherein another one from among the first contact portion, the second contact portion, the third contact portion, and the fourth contact portion is connected to a ground of the printed circuit board.

7. The electronic device according to claim 1, wherein the first metal is a titanium alloy and the second metal is an aluminum alloy.

8. The electronic device according to claim 1, wherein the first metal is stainless steel and the second metal is an aluminum alloy.

9. An electronic device comprising:
a display;
a rear cover; and
a frame structure at least partially between the display and the rear cover,
wherein the frame structure comprises:
a first side portion defining a first portion of a first side surface of the electronic device, the first side portion comprising a first clad structure comprising a first metal and a second metal, the first metal of the first clad structure being farther than the second metal of the first clad structure towards an outside of the electronic device;
a second side portion defining a first portion of a second side surface of the electronic device, the second side portion comprising a second clad structure comprising the first metal and the second metal, the first metal of the second clad structure being farther than the second metal of the second clad structure towards the outside of the electronic device;
a corner portion defining, between the first side portion and the second side portion, a second portion of the first side surface and a second portion of the second side surface, the corner portion comprising a first antenna feed comprising the first metal; and
a support portion supporting the display, the support portion connected to the first side portion and the corner portion, and comprising the second metal.

10. The electronic device according to claim 9, wherein the second side portion comprises a second antenna feed comprising the second metal.

11. The electronic device according to claim 10, further comprising a printed circuit board supported by the support portion,
wherein the corner portion comprises a ground point comprising the first metal, and
wherein the ground point is electrically connected to a ground surface of the printed circuit board.

12. The electronic device according to claim 11, wherein the first antenna feed and the ground point protrude in different directions toward an interior of the electronic device, respectively.

13. The electronic device according to claim 11, wherein the printed circuit board comprises a first communication circuit configured to support a first frequency band, and a second communication circuit configured to support a second frequency band,
wherein the first antenna feed is electrically connected to the first communication circuit via a first terminal on the printed circuit board, and
wherein the second antenna feed is electrically connected to the second communication circuit via a second terminal on the printed circuit board.

14. The electronic device according to claim 9, wherein the second metal of the first side portion comprises:
a first surface facing toward an interior of the electronic device; and
a second surface perpendicular to the first surface and overlapping with the support portion in a direction towards a front of the electronic device,
wherein the first surface and the support portion are connected by a first insert injection molding, and
wherein the second surface and the support portion are connected by a first welding portion.

15. The electronic device according to claim 14, wherein the first metal of the corner portion comprises:
a third surface facing toward the interior of the electronic device; and
a fourth surface perpendicular to the third surface and overlapping with the support portion in the direction towards the front of the electronic device,
wherein the third surface and the support portion are connected by the first insert injection molding, and
wherein the fourth surface and the support portion are connected by a second welding portion.

16. The electronic device according to claim 15, further comprising a second insert injection molding that is on the first welding portion and the second welding portion.

17. The electronic device according to claim 16, wherein the second insert injection molding is on at least a portion of the first insert injection molding.

18. The electronic device according to claim 9, wherein a radius of curvature of a region, where the second portion of the first side surface and the second portion of the second side surface meet, of the corner portion is greater than 0.5 mm and less than 8 mm.

19. A foldable electronic device comprising:
a hinge module;
a first housing connected to the hinge module and configured to fold about the hinge module;
a second housing connected to the hinge module and configured to fold about the hinge module; and
a hinge cover connected to the hinge module,
wherein at least a portion of the first housing, the second housing, and the hinge cover comprise a frame of the foldable electronic device,
wherein the foldable electronic device further comprises a support portion inside the frame,
wherein the frame comprises:
a hinge side frame portion connected to the hinge cover and comprising at least a portion defining a first portion of a side surface of the foldable electronic device in a state in which the first housing and the second housing are folded;
an edge frame portion opposite to the hinge side frame portion and defining a second portion of the side surface; and
a corner frame portion on one side of the edge frame portion and defining a corner portion of the side surface,
wherein the hinge side frame portion and the corner frame portion comprise a first metal,
wherein the edge frame portion comprises a clad structure comprising the first metal and a second metal, that is different from the first metal, and
wherein the support portion is connected to the corner frame portion and the edge frame portion by welding.

20. The foldable electronic device of claim 19, wherein the corner frame portion comprises a first antenna feed that protrudes toward an inside of the foldable electronic device, the first antenna feed comprising the first metal, and
wherein the edge frame portion comprises a second antenna feed that protrudes toward the inside of the foldable electronic device, the second antenna feed comprising the second metal.
